(19) United States
(12) Patent Application Publication
(10) Pub. No.: US 2026/0271589 A1
(43) Pub. Date: Sep. 10, 2026

(54) DISPLAY DEVICE, METHOD FOR MANUFACTURING THE SAME, AND ELECTRONIC DEVICE INCLUDING THE DISPLAY DEVICE

(71) Applicant: Samsung Display Co., LTD., Yongin-si (KR)

(72) Inventors: Jeong Weon SEO, Yongin-si (KR); Su Hyoung KANG, Yongin-si (KR); Tae Woo PARK, Yongin-si (KR); Gwang Taek LEE, Yongin-si (KR); Sung Kook LEE, Yongin-si (KR); Jung Kyu LEE, Yongin-si (KR)

(21) Appl. No.: 19/371,201

(22) Filed: Oct. 28, 2025

(30) Foreign Application Priority Data
Mar. 4, 2025 (KR) 10-2025-0027379
May 9, 2025 (KR) 10-2025-0060235

(51) Int. Cl. H10K 59/80; H10K 59/12

(52) U.S. Cl. CPC H10K 59/873; H10K 59/1201

(57) ABSTRACT

A display device includes, a display panel including a main area and a sub-area disposed on one side of the main area and configured to be bendable, and a cover window including a base layer disposed on the display panel and a coating layer disposed on the base layer, a first residual trace disposed on a first side next (adjacent) to the sub-area and a second residual trace disposed on at least one of remaining sides of the cover window excluding the first side.

This application claims priority to Korean Patent Application No. 10-2025-0027379, filed on Mar. 4, 2025, and Korean Patent Application No. 10-2025-0060235, filed on May 9, 2025, and all the benefits accruing therefrom under 35 U.S.C. § 119, the contents of which in their entirety are herein incorporated by reference.

### BACKGROUND

### 1. Field

The disclosure relates to a display device, a method for manufacturing the display device, and an electronic device including the same.

### 2. Description of the Related Art

As the information society develops, the demand for display devices for displaying images continues to increase and diversify. The display devices may be display devices such as liquid crystal displays (“LCDs”), field emission displays (“FEDs”), or light-emitting displays (“LEDs”). The light-emitting display may include an organic light-emitting display including organic light-emitting diode elements as light-emitting elements, an inorganic light-emitting display including inorganic light-emitting diode elements as light-emitting elements, or the like.

The display device may include a cover window for protecting a display panel. The cover window may protect the display panel from an external impact and a scratch. Recently, as foldable displays and flexible displays develop, the application of materials having flexibility continues to increase. In addition, the demand for improving surface quality characteristics of the cover window continues to increase.

### SUMMARY

Features of the disclosure provide a display device including a cover window whose surface quality is improved, a method for manufacturing the display device, and an electronic device including the same.

Features of the disclosure also provide a display device in which damage to a pad portion of a display panel is minimized, a method for manufacturing the display device, and an electronic device including the same.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, there is provided a display device including, a display panel including a main area and a sub-area disposed on one side of the main area and configured to be bendable, and a cover window including a base layer disposed on the display panel and a coating layer disposed on the base layer, wherein the cover window includes a first residual trace disposed on a first side next (adjacent) to the sub-area and a second residual trace disposed on at least one of remaining sides of the cover window excluding the first side.

In an embodiment, the first residual trace is disposed on a side surface of the coating layer on the first side, and the second residual traces are disposed on the base layer and the coating layer, respectively, on the at least one side.

In an embodiment, the first residual trace is disposed only on a portion of the side surface of the coating layer, and is next (adjacent) to an upper surface of the coating layer.

In an embodiment, the first residual trace is a burr and the second residual trace is a heat-affected zone (“HAZ”).

In an embodiment, the second residual trace disposed on the base layer and the second residual trace disposed on the coating layer have different properties.

In an embodiment, the coating layer includes a chamfered surface disposed between a side surface and an upper surface, and the first residual trace is disposed on the chamfered surface of the coating layer on the first side.

In an embodiment, on a side corresponding to the at least one side of the cover window, a side surface of the display panel is disposed in a straight line with a side surface of the cover window

In an embodiment, the display panel includes a third residual trace on the side corresponding to the at least one side of the cover window.

In an embodiment, the third residual trace is a HAZ.

In an embodiment, the display device may further comprise an upper protection layer disposed on the cover window, wherein the upper protection layer includes a light-blocking portion overlapping the first residual trace and the second residual trace.

In an embodiment, the display device may further comprise a polarizing layer disposed between the display panel and the cover window.

In an embodiment of the disclosure, there is provided a method for manufacturing a display device, including, forming a first cutting line in a display panel, forming a second cutting line in a base layer, bonding the display panel and the base layer to each other, forming a coating layer on the base layer, forming a third cutting line in the display panel, the base layer, and the coating layer, and splitting and removing dummy areas of the display panel, the base layer, and the coating layer along the first cutting line, the second cutting line, and the third cutting line, wherein the third cutting line crosses each of the first cutting line and the second cutting line.

In an embodiment, the first cutting line is next (adjacent) to one side of the display panel, and the second cutting line is next (adjacent) to the one side of the display panel.

In an embodiment, the first cutting line and the third cutting line are formed using a laser beam.

In an embodiment, the third cutting line continuously penetrates through the display panel, the base layer, and the coating layer.

In an embodiment, the coating layer is formed by applying ink by a coating device, and a scan direction of the coating device is parallel to an extension direction of the second cutting line.

In an embodiment, a shape control block is disposed on the base layer, and a height of the coating layer is greater than a height of the shape control block.

In an embodiment, a burr is formed by removing a portion of the coating layer disposed at a higher level than the shape control block.

In an embodiment, the shape control block includes a protrusion portion.

In an embodiment of the disclosure, there is provided an electronic device including, a display device displaying an image, a processor providing an image driving signal to the display device, and a power module supplying power to the display device and the processor, wherein the display device includes, a display panel including a main area and a sub-area disposed on one side of the main area and configured to be bendable, and a cover window including a base layer disposed on the display panel and a coating layer disposed on the base layer, and the cover window includes a first residual trace disposed on a first side next (adjacent) to the sub-area and a second residual trace disposed on at least one of remaining sides of the cover window excluding the first side.

With a display device, a method for manufacturing the display device, and an electronic device including the same according to the disclosure, the display device may include a cover window whose surface quality is improved.

With the display device, the method for manufacturing the display device, and the electronic device including the same according to the disclosure, damage to a pad portion of a display panel may be minimized.

The effects of the disclosure are not limited to the aforementioned effects, and various other effects are included in the specification.

### BRIEF DESCRIPTION OF THE DRAWINGS

The above and other advantages and features of the disclosure will become more apparent by describing in detail embodiments thereof with reference to the attached drawings, in which:

FIG. 1 is a schematic perspective view illustrating an embodiment of an electronic device;

FIG. 2 is a perspective view illustrating an embodiment of a display device included in the electronic device;

FIG. 3 is a plan view illustrating an embodiment of a display device;

FIG. 4 is a cross-sectional view illustrating an embodiment of the display device;

FIG. 5 is a perspective view illustrating another embodiment of an unfolded state of a display device;

FIG. 6 is a perspective view illustrating another embodiment of a folded state of the display device;

FIG. 7 is a perspective view illustrating another embodiment of an unfolded state of a display device;

FIG. 8 is a perspective view illustrating another embodiment of a folded state of the display device;

FIG. 9 is a plan view illustrating embodiments of the display device of FIGS. 5 to 8;

FIG. 10 is a schematic cross-sectional view illustrating embodiments of the display device of FIGS. 5 to 8;

FIG. 11 is a detailed cross-sectional view illustrating embodiments of the display device of FIGS. 5 to 8;

FIG. 12 is a cross-sectional view illustrating an embodiment of a display panel;

FIG. 13 is a front perspective view illustrating an embodiment of a cover window;

FIG. 14 is a back perspective view illustrating an embodiment of the cover window;

FIG. 15 is a plan view illustrating an embodiment of the cover window;

FIG. 16 is a cross-sectional view taken along line X1-X1′ of FIG. 15;

FIG. 17 is a cross-sectional view illustrating an embodiment of a cross section taken along line X2-X2′ of FIG. 15;

FIG. 18 is a cross-sectional view illustrating another embodiment of a cross section taken along line X2-X2′ of FIG. 15;

FIG. 19 is a flowchart illustrating an embodiment of a method for manufacturing the display device;

FIG. 20 is a plan view illustrating an operation S100 of FIG. 19;

FIG. 21 is a plan view illustrating an operation S200 of FIG. 19;

FIG. 22 is a plan view illustrating an operation S300 of FIG. 19;

FIG. 23 is a plan view illustrating an operation S400 of FIG. 19;

FIG. 24 is a plan view illustrating an operation S500 of FIG. 19;

FIG. 25 is a plan view illustrating an operation S600 of FIG. 19;

FIG. 26 is a cross-sectional view along line X3-X3′ of FIG. 20, illustrating the operation S100 of FIG. 19;

FIGS. 27A to 27C are cross-sectional views along line X4-X4′ of FIG. 21, illustrating several embodiments of the operation S200 of FIG. 19;

FIG. 28 is a cross-sectional view along line X4-X4′ of FIG. 21, illustrating another embodiment of the operation S200 of FIG. 19;

FIG. 29 is a cross-sectional view along line X5-X5′ of FIG. 22, illustrating an embodiment of the operation S300 of FIG. 19;

FIG. 30 is a cross-sectional view along line X5-X5′ of FIG. 22, illustrating another embodiment of the operation S300 of FIG. 19;

FIG. 31 is a cross-sectional view along line X6-X6′ of FIG. 23, illustrating an embodiment of the operation S400 of FIG. 19;

FIG. 32 is a cross-sectional view along line X6-X6′ of FIG. 23, illustrating another embodiment of the operation S400 of FIG. 19;

FIG. 33 is a cross-sectional view along line X7-X7′ of FIG. 24, illustrating an embodiment of the operation S500 of FIG. 19;

FIG. 34 is a cross-sectional view along line X7-X7′ of FIG. 24, illustrating another embodiment of the operation S500 of FIG. 19;

FIG. 35 is a cross-sectional view along line X8-X8′ of FIG. 25, illustrating an embodiment of the operation S600 of FIG. 19;

FIG. 36 is a cross-sectional view along line X8-X8′ of FIG. 25, illustrating another embodiment of the operation S600 of FIG. 19;

FIG. 37 is a cross-sectional view along line X6-X6′ of FIG. 23, illustrating another embodiment of the operation S400 of a method for manufacturing a display device;

FIG. 38 is a cross-sectional view along line X8-X8′ of FIG. 25, illustrating another embodiment of the operation S600 of the method for manufacturing a display device of FIG. 36;

FIG. 39 is a block diagram of another embodiment of an electronic device; and

FIG. 40 is schematic views of an embodiment of electronic devices.

### DETAILED DESCRIPTION

The disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will filly convey the scope of the disclosure to those skilled in the art.

It will also be understood that when a layer is referred to as being “on” another layer or substrate, it may be directly on the other layer or substrate, or intervening layers may also be present. The same reference numbers indicate the same components throughout the specification.

Hereinafter, embodiments of the disclosure will be described in detail with reference to the accompanying drawings.

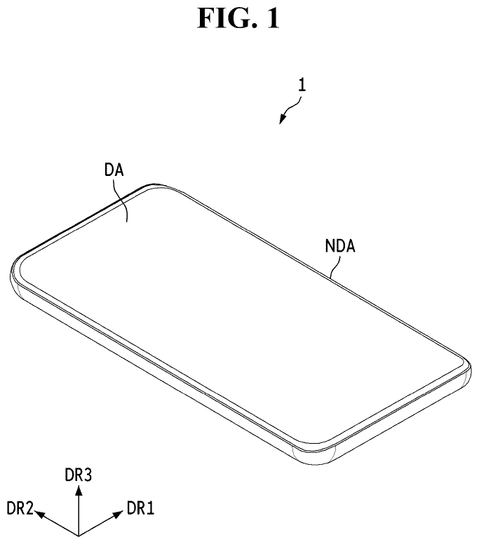

FIG. 1 is a schematic perspective view illustrating an embodiment of an electronic device.

Referring to FIG. 1, an electronic device 1 displays a moving image or a still image. The electronic device 1 may refer to all electronic devices that provide display screens. In an embodiment, televisions, laptop computers, monitors, billboards, the Internet of Things (“IoT”), mobile phones, smartphones, tablet personal computers (“PCs”), electronic watches, smart watches, watch phones, head disposed (e.g., mounted) displays, mobile communication terminals, electronic notebooks, electronic books, portable multimedia players (“PMPs”), navigation devices, game machines, digital cameras, camcorders, or the like, that provide display screens, may be included in the electronic device 1, for example.

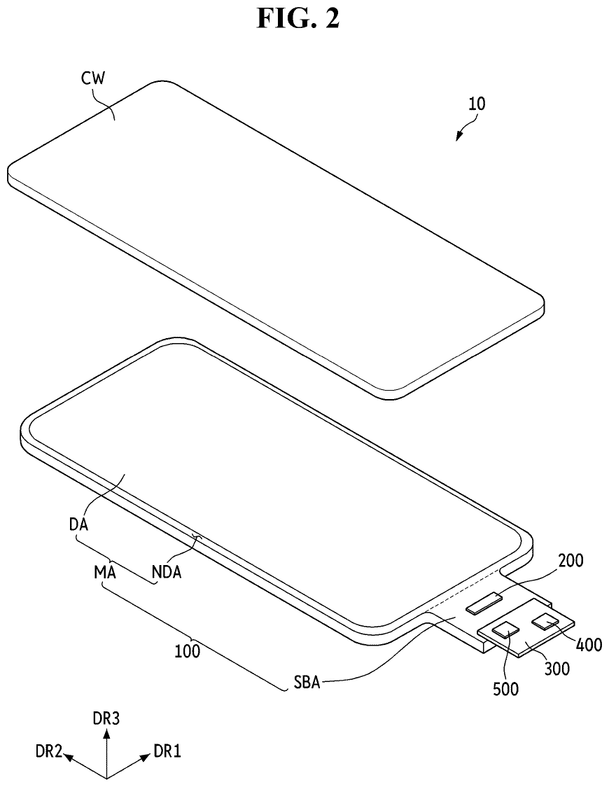

The electronic device 1 may include a display device 10 (refer to FIG. 2) providing a display screen. In embodiments, the display device may include an inorganic light-emitting diode display device, an organic light-emitting display device, a quantum dot light-emitting display device, a plasma display device, a field emission display device, or the like. Hereinafter, a case where an organic light-emitting diode display device is applied in an embodiment of the display device will be described as one of the embodiments, but the disclosure is not limited thereto, and the same technical spirit may be applied to other display devices when applicable.

A shape of the electronic device 1 may be variously modified. In an embodiment, the electronic device 1 may have a shape such as a quadrangular shape, e.g., rectangular shape with a width greater than a length, a quadrangular shape, e.g., rectangular shape with a length greater than a width, a square shape, a quadrangular shape with rounded corners (vertices), other polygonal shapes, or a circular shape, for example. A shape of a display area DA of the electronic device 1 may also be similar to an overall shape of the electronic device 1. The electronic device 1 having a quadrangular shape, e.g., rectangular shape having a greater length in a second direction DR2 than in a first direction DR1 has been illustrated in FIG. 1.

In the drawings, the first direction DR1 and the second direction DR2 are horizontal directions, respectively, and cross each other. In an embodiment, the first direction DR1 and the second direction DR2 may be orthogonal to each other, for example. In addition, a third direction DR3 may be a perpendicular direction crossing, e.g., orthogonal to, the first direction DR1 and the second direction DR2. Unless otherwise defined, directions indicated by arrows of the first to third directions DR1, DR2, and DR3 may be also referred to as one side, and directions opposite to one side may be also referred to as an opposite side. In addition, the terms “on”, “upper side”, “upper portion”, “top, and “upper surface” as used herein refer to a direction toward which an arrow of the third direction DR3 is directed in the drawings, and the terms “below”, “lower side”, “lower portion”, “bottom, and “lower surface” used as herein refer to a direction opposite to the direction toward which the arrow of the third direction DR3 is directed in the drawings.

The electronic device 1 may include a display area DA and a non-display area NDA. The display area DA is an area where a screen may be displayed, and the non-display area NDA is an area where the screen is not displayed. The display area DA may also be also referred to as an active area, and the non-display area NDA may also be also referred to as a non-active area. The display area DA may occupy substantially the center of the electronic device 1.

FIG. 2 is a perspective view illustrating an embodiment of a display device included in the electronic device.

Referring to FIG. 2 in addition FIG. 1, the electronic device 1 in an embodiment may include the display device 10. The display device 10 may provide a screen displayed on the electronic device 1. The display device 10 may have a shape similar to that of the electronic device 1 in a plan view. In an embodiment, the display device 10 may have a shape similar to a quadrangular shape, e.g., rectangular shape having short sides in the first direction DR1 and long sides in the second direction DR2, for example. A corner where the short side in the first direction DR1 and the long side in the second direction DR2 meet may be rounded with a curvature, but is not limited thereto, and may also be right-angled. The shape of the display device 10 in a plan view is not limited to the quadrangular shape, e.g., rectangular shape, and may be a shape similar to other polygonal shapes, a circular shape, or an elliptical shape.

The display device 10 may include a cover window CW, a display panel 100, a display driver 200, a circuit board 300, a touch driver 400, and a power supply unit 500.

The display panel 100 may include a main area MA and a sub-area SBA.

The main area MA may include a display area DA including pixels displaying an image and a non-display area NDA disposed around the display area DA. The display area DA may be disposed at the center of the main area MA, and the non-display area NDA may surround the display area DA. The display area DA may emit light from a plurality of emission areas or a plurality of opening areas. In an embodiment, the display panel 100 may include pixel circuits including switching elements, a pixel defining film defining the emission areas or the opening areas, and self-light-emitting elements, for example.

In an embodiment, the self-light-emitting element may include at least one of an organic light-emitting diode (“LED”) including an organic light-emitting layer, a quantum dot LED including a quantum dot light-emitting layer, an inorganic LED including an inorganic semiconductor, and a micro LED, for example, but is not limited thereto.

The non-display area NDA may be an area outside the display area DA. The non-display area NDA may be defined as an edge area of the main area MA of the display panel 100. The non-display area NDA may include a gate driver supplying gate signals to gate lines and fan-out lines connecting the display driver 200 and the display area DA to each other.

The sub-area SBA may be an area extending from one side of the main area MA. The sub-area SBA may include a flexible material that may be bent, folded, and rolled. In an embodiment, when the sub-area SBA is bent, the sub-area SBA may overlap the main area MA in a thickness direction (e.g., the third direction DR3), for example. The sub-area SBA may include the display driver 200 and pad portions connected to the circuit board 300.

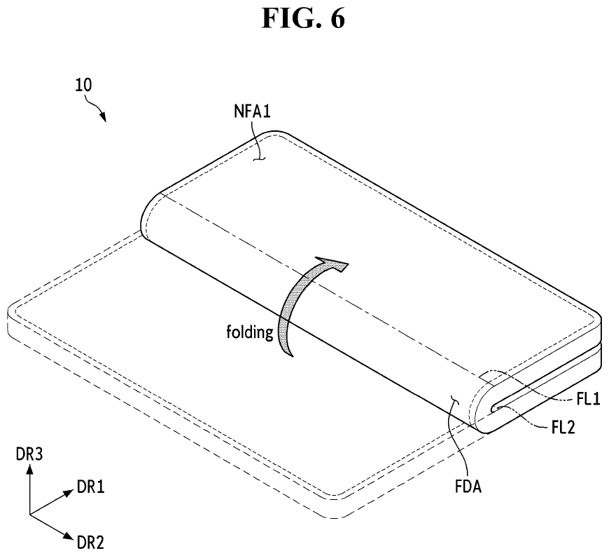

In another embodiment, the sub-area SBA may be omitted, and the display driver 200 and the pad portions may be disposed in the non-display area NDA. In this case, the circuit board 300 may be bent instead of the sub-area SBA, as illustrated in FIG. 6 to be described later.

The display driver 200 may output signals and voltages for driving the display panel 100. The display driver 200 may supply data voltages to data lines. The display driver 200 may supply source voltages to power lines and supply gate control signals to the gate driver.

The display driver 200 may be formed as an integrated circuit (“IC”) and disposed (e.g., mounted) on the display panel 100 in a chip on glass (“COG”) manner, a chip on plastic (“COP”) manner, or an ultrasonic bonding manner. In an embodiment, the display driver 200 may be disposed in the sub-area SBA, and may overlap the main area MA in the thickness direction by bending of the sub-area SBA. In another embodiment, the display driver 200 may be disposed (e.g., mounted) on the circuit board 300.

The circuit board 300 may be attached onto the pad portions of the display panel 100 using an anisotropic conductive film (“ACF”). Lead lines of the circuit board 300 may be electrically connected to the pad portions of the display panel 100. The circuit board 300 may be a flexible printed circuit board, a printed circuit board, or a flexible film such as a chip on film.

The touch driver 400 may be disposed (e.g., mounted) on the circuit board 300. The touch driver 400 may be connected to a touch sensing unit of the display panel 100. The touch driver 400 may supply touch driving signals to a plurality of touch electrodes of the touch sensing unit and sense change amounts in capacitance between the plurality of touch electrodes. In an embodiment, the touch driving signal may be a pulse signal having a selected frequency, for example. The touch driver 400 may decide whether or not an input has occurred and calculate input coordinates, based on the change amounts in capacitance between the plurality of touch electrodes. The touch driver 400 may be formed as an integrated circuit (“IC”).

The power supply unit 500 may be disposed on the circuit board 300 and may supply source voltages to the display driver 200 and the display panel 100. The power supply unit 500 may generate a driving voltage and supply the driving voltage to a driving voltage line, and may generate a common voltage and supply the common voltage to a common electrode. In an embodiment, the driving voltage may be a high-potential voltage for driving a light-emitting element, and the common voltage may be a low-potential voltage for driving the light-emitting element, for example. The power supply unit 500 may generate an initialization voltage and supply the initialization voltage to an initialization voltage line, may generate a reference voltage and supply the reference voltage to a reference voltage line, may generate a bias voltage and supply the bias voltage to a bias voltage line, and may generate a reset voltage and supply the reset voltage to a reset voltage line.

The cover window CW may be disposed on a front surface of the display panel 100 to protect the front surface of the display panel 100 from an external impact. The cover window CW may include or consist of a transparent material. In some embodiments, the cover window CW may include a polymer resin in order to improve surface quality of the display device 10. In an embodiment, the cover window CW may be formed by applying and curing a liquid polymer resin, for example. Accordingly, the cover window CW may planarize waviness or crease occurring in an underlying structure of the cover window CW to improve the surface quality of the display device 10.

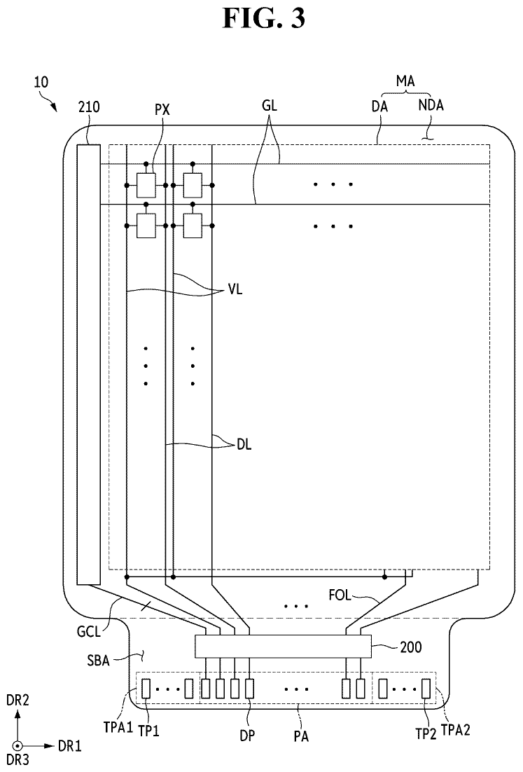

FIG. 3 is a plan view illustrating an embodiment of a display device.

Referring to FIG. 3, the display device 10 may include a main area MA and a sub-area SBA. The main area MA may include a display area DA and a non-display area NDA.

The display area DA may be disposed approximately at the center of the display panel 100. A plurality of pixels PX, a plurality of gate lines GL, a plurality of data lines DL, and a plurality of power lines VL may be disposed in the display area DA. Each of the plurality of pixels PX may be defined as a minimum unit emitting light.

The plurality of gate lines GL may supply gate signals received from a gate driver 210 to the plurality of pixels PX. The plurality of gate lines GL may extend in the first direction DR1, and may be spaced apart from each other in the second direction DR2 crossing the first direction DR1.

The plurality of data lines DL may supply data voltages received from the display driver 200 to the plurality of pixels PX. The plurality of data lines DL may extend in the second direction DR2, and may be spaced apart from each other in the first direction DR1.

The plurality of power lines VL may supply source voltages received from the display driver 200 to the plurality of pixels PX. Here, the source voltage may be at least one of a driving voltage, an initialization voltage, a reference voltage, and a low-potential voltage. The plurality of power lines VL may extend in the second direction DR2, and may be spaced apart from each other in the first direction DR1.

The non-display areas NDA may surround the display area DA. The gate driver 210, fan-out lines FOL, and gate control lines GCL may be disposed in the non-display area NDA. The gate driver 210 may generate a plurality of gate signals based on a gate control signal, and may sequentially supply the plurality of gate signals to the plurality of gate lines GL according to a set order.

The fan-out lines FOL may extend from the display driver 200 to the display area DA. The fan-out lines FOL may supply the data voltages received from the display driver 200 to the plurality of data lines DL.

The gate control line GCL may extend from the display driver 200 to the gate driver 210. The gate control line GCL may supply the gate control signal received from the display driver 200 to the gate driver 210.

The sub-area SBA may be an area extending from one side of the main area MA. The sub-area SBA may include a flexible material that may be bent, folded, and rolled. In an embodiment, when the sub-area SBA is bent, the sub-area SBA may overlap the main area MA in the thickness direction (e.g., the third direction DR3), for example. The sub-area SBA may include the display driver 200, a pad area PA, and first and second touch pad areas TPA1 and TPA2.

The display driver 200 may output signals and voltages for driving the display panel 100 to the fan-out lines FOL. The display driver 200 may supply the data voltages to the data lines DL through the fan-out lines FOL. The data voltages may be supplied to the plurality of pixels PX, and may control luminance of the plurality of pixels PX. The display driver 200 may supply the gate control signal to the gate driver 210 through the gate control lines GCL.

The pad area PA, the first touch pad area TPA1, and the second touch pad area TPA2 may be disposed at an edge of the sub-area SBA. The pad area PA, the first touch pad area TPA1, and the second touch pad area TPA2 may be electrically connected to the circuit board 300 using an adhesive member. In an embodiment, the first touch pad area TPA1 may include first touch pad portions TP1, and the second touch pad area TPA2 may include second touch pad portions TP2.

The pad area PA may include a plurality of display pad portions DP. The plurality of display pad portions DP may be connected to a graphic system through the circuit board 300. The plurality of display pad portions DP may be connected to the circuit board 300 to receive digital video data, and may supply the digital video data to the display driver 200.

In some embodiments, although not illustrated in FIG. 3, an area such as the pad area PA may be further included below the display driver 200. When the display driver 200 is formed as an integrated circuit (“IC”) and disposed (e.g., mounted) on the display panel 100 or on the circuit board 300, the area disposed below the display driver 200 may include a plurality of display pad portions DP, similar to the pad area PA. A description of the pad area PA, the display pad portion DP, or the like, in the disclosure may be equally applied to the area disposed below the display driver 200.

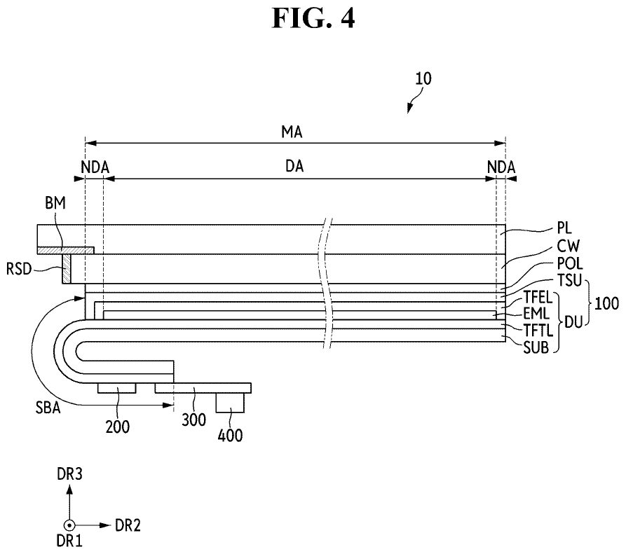

FIG. 4 is a cross-sectional view illustrating an embodiment of the display device.

Referring to FIG. 4 in addition to FIG. 3, the display device 10 may include a display panel 100, a polarizing layer POL, a cover window CW, and an upper protection layer PL. The display panel 100 may include a display layer DU and a touch sensing layer TSU (e.g., a touch layer). The display layer DU may include a substrate SUB, a thin film transistor layer TFTL (e.g., a circuit layer), a light-emitting element layer EML, and a thin film encapsulation layer TFEL.

The substrate SUB may be a base substrate or a base member. The substrate SUB may be a flexible substrate that may be bent, folded, and rolled. In an embodiment, the substrate SUB may include a polymer resin such as polyimide (“PI”), for example, but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include the gate lines GL, the data lines DL, the power lines VL, the gate control lines GCL, the fan-out lines FOL connecting the display driver 200 and the data lines DL to each other, and lead lines connecting the display driver 200 and the pad portion to each other, as illustrated in FIG. 3. Each of the thin film transistors may include a semiconductor region, a source electrode, a drain electrode, and a gate electrode. In an embodiment, when the gate driver is formed on one side of the non-display area NDA of the display panel 100, the gate driver may include thin film transistors, for example.

The thin film transistor layer TFTL may be disposed in the display area DA, the non-display area NDA, and the sub-area SBA. The thin film transistors of each of the pixels, the gate lines GL, the data lines DL, and the power lines VL of the thin film transistor layer TFTL may be disposed in the display area DA. The gate control lines GCL and the fan-out lines FOL of the thin film transistor layer TFTL may be disposed in the non-display area NDA. The lead lines of the thin film transistor layer TFTL may be disposed in the sub-area SBA.

The light-emitting element layer EML may be disposed on the thin film transistor layer TFTL. The light-emitting element layer EML may include a plurality of light-emitting elements each including a first electrode, a second electrode, and a light-emitting layer to emit light and a pixel defining layer (e.g., a bank layer) defining the pixels. The plurality of light-emitting elements of the light-emitting element layer EML may be disposed in the display area DA.

The thin film encapsulation layer TFEL may cover an upper surface and side surfaces of the light-emitting element layer EML, and may protect the light-emitting element layer EML. The thin film encapsulation layer TFEL may include at least one inorganic film and at least one organic film for encapsulating the light-emitting element layer EML.

The touch sensing layer TSU may be disposed on the thin film encapsulation layer TFEL. The touch sensing layer TSU may include a plurality of touch electrodes for sensing a user's touch in a capacitance manner and touch lines connecting the plurality of touch electrodes and the touch driver 400 to each other. In an embodiment, the touch sensing layer TSU may sense the user's touch in a mutual capacitance manner or a self-capacitance manner, for example.

In another embodiment, the touch sensing layer TSU may be disposed on a separate substrate disposed on the display layer DU. In this case, the substrate supporting the touch sensing layer TSU may be a base member encapsulating the display layer DU.

The plurality of touch electrodes of the touch sensing layer TSU may be disposed in a touch sensor area overlapping the display area DA. The touch lines of the touch sensing layer TSU may be disposed in a touch peripheral area overlapping the non-display area NDA.

The polarizing layer POL may be disposed on the display panel 100 in order to prevent a phenomenon in which external light is reflected from the display panel 100 to deteriorate the visibility of an image displayed on the display panel 100. The polarizing layer POL may include a first base member, a linear polarizer, a phase retardation film such as a λ/4 plate (quarter-wave plate), and a second base member. The first base member, the phase retardation film, the linear polarizer, and the second base member of the polarizing layer POL may be sequentially stacked on the display panel 100.

In another embodiment, an optical layer including a color filter may be disposed instead of the polarizing layer POL between the display panel 100 and the cover window CW. The optical layer may prevent a phenomenon in which external light is reflected from the display panel 100 to deteriorate the visibility of an image displayed on the display panel 100, by including a plurality of color filters.

The cover window CW may be disposed on the polarizing layer POL. The cover window CW may protect the front surface of the display panel 100 from an external impact. The cover window CW may be attached onto the polarizing layer POL by a transparent adhesive member such as an optically clear adhesive (“OCA”) film or an optically clear resin (“OCR”).

The cover window CW may include or consist of a transparent material. In some embodiments, the cover window CW may include a polymer resin in order to improve surface quality of the display device 10. In an embodiment, the cover window CW may be formed by applying and curing a liquid polymer resin, for example. Accordingly, the cover window CW may planarize waviness or crease occurring in an underlying structure of the cover window CW to improve the surface quality of the display device 10.

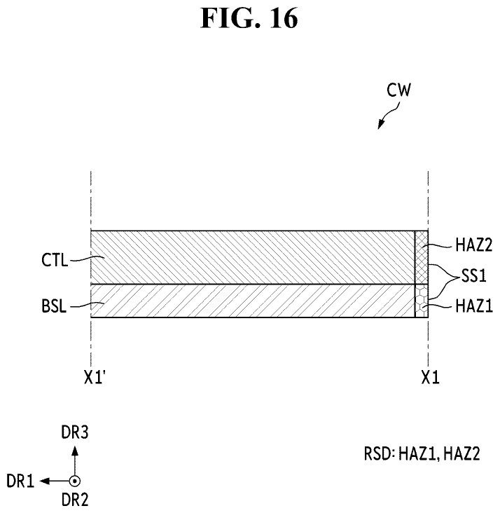

The cover window CW may include a residual trace RSD. The residual trace RSD is described later with reference to FIGS. 16 to 18.

The upper protection layer PL may perform at least one of an anti-scattering function of the cover window CW an impact absorption function, an anti-scratch function, an anti-fingerprint function, an anti-glare function. In some embodiments, the upper protection layer PL may include plastic such as polyethylene terephthalate (“PET”) or polyimide.

A light-blocking portion BM may include a light-absorbing material. In an embodiment, the light-blocking portion BM may include an inorganic black pigment or an organic black pigment, for example. The inorganic black pigment may be carbon black, and the organic black pigment may include at least one of Lactam Black, Perylene Black, and Aniline Black, but the disclosure is not limited thereto.

It has been illustrated in FIG. 4 that the light-blocking portion BM is disposed only on one side surface of the upper protection layer PL, but the disclosure is not limited thereto. In an embodiment, just as the non-display area NDA surrounds the display area DA as illustrated in FIG. 3, the light-blocking portion BM may be disposed in the non-display area NDA so as to surround the display area DA. In other words, the light-blocking portion BM may surround an edge of the upper protection layer PL.

The light-blocking portion BM may overlap the residual trace RSD of the cover window CW in the third direction DR3. Accordingly, the residual trace RSD of the cover window CW may not be viewed from the outside by the light-blocking portion BM of the upper protection layer PL.

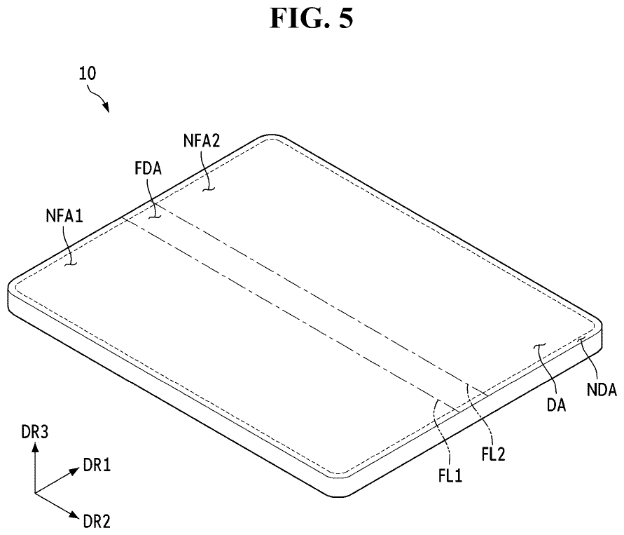

FIG. 5 is a perspective view illustrating another embodiment of an unfolded state of a display device. FIG. 6 is a perspective view illustrating another embodiment of a folded state of the display device.

Referring to FIGS. 5 and 6, a first state of a display device 10 that is not folded at folding lines FL1 and FL2 and is unfolded is illustrated in FIG. 5, and a second state of the display device 10 that is folded at the folding lines FL1 and FL2 is illustrated in FIG. 6.

The display device 10 in an embodiment is a device that displays a moving image or a still image, and may be used as a display screen of each of various products such as televisions, laptop computers, monitors, billboards, and the Internet of Things (“IoT”) as well as portable electronic devices such as mobile phones, smartphones, tablet personal computers (“PCs”), smart watches, watch phones, mobile communication terminals, electronic notebooks, electronic books, portable multimedia players (“PMPs”), navigation devices, and ultra mobile PCs (“UMPCs”).

In the drawings, the first direction DR1 is a direction parallel to one side of the display device 10 in a plan view, and may be a transverse direction of the display device 10, for example. The second direction DR2 is a direction parallel to an opposite side of the display device 10 in contact with one side of the display device 10 in a plan view, and may be a longitudinal direction of the display device 10. The third direction DR3 may be a thickness direction of the display device 10.

The display device 10 may have a quadrangular shape such as a quadrangular shape, e.g., rectangular shape in a plan view. Each of corners of the display device 10 may have a right-angled shape in a plan view or a round shape in a plan view. A front surface of the display device 10 may include two short sides disposed in the first direction DR1 and two long sides disposed in the second direction DR2.

The display device 10 may include a display area DA and a non-display area NDA. A shape of the display area DA in a plan view may follow the shape of the display device 10 in a plan view. In an embodiment, when the shape of the display device 10 in a plan view is the quadrangular shape, e.g., rectangular shape, the shape of the display area DA in a plan view may also be a quadrangular shape, e.g., rectangular shape.

The display area DA may be an area displaying an image by including a plurality of pixels. The non-display area NDA may be an area that does not display an image because it does not include pixels. The non-display area NDA may be disposed around the display area DA. The non-display area NDA may surround the display area DA, but the disclosure is not limited thereto. The display area DA may be partially surrounded by the non-display area NDA.

The display device 10 may be maintained in both a first state, which is an unfolded state, and a second state, which is a folded state. In an embodiment, the display device 10 may be folded in an in-folding manner in which the display areas DA face each other as illustrated in FIG. 6. In this case, front surfaces of the display device 10 may face each other when the display device 10 is folded. In another embodiment, the display device 10 may be folded in an out-folding manner so that back surfaces thereof face each other.

The display device 10 may include a folding area FDA, a first non-folding area NFA1, and a second non-folding area NFA2. The folding area FDA may be an area where the display device 10 is bent or folded, and the first non-folding area NFA1 and the second non-folding area NFA2 may be areas where the display device 10 is not bent or folded. In an embodiment, the first non-folding area NFA1 and the second non-folding area NFA2 may be flat areas of the display device 10.

The first non-folding area NFA1 may be disposed on one side, e.g., the left side, of the folding area FDA. The second non-folding area NFA2 may be disposed on an opposite side, e.g., the right side, of the folding area FDA. The folding area FDA is an area defined by a first folding line FL1 and a second folding line FL2, and may be an area where the display device 10 is bent with a selected curvature. The first folding line FL1 may be a boundary between the folding area FDA and the first non-folding area NFA1, and the second folding line FL2 may be a boundary between the folding area FDA and the second non-folding area NFA2.

The first folding line FL1 and the second folding line FL2 may extend in the second direction DR2 as illustrated in FIGS. 5 and 6, and in this case, the display device 10 may be folded based on the second direction DR2. For this reason, a length of the display device 10 in the first direction DR1 may be reduced by approximately half, and thus, a user may conveniently carry the display device 10.

The first non-folding area NFA1 may be disposed on one side, e.g., the left side, of the folding area FDA. The second non-folding area NFA2 may be disposed on an opposite side, e.g., the right side, of the folding area FDA. Here, the left side may refer to one side in the first direction DR1, and the right side may refer to an opposite side in the first direction DR1.

When the first folding line FL1 and the second folding line FL2 extend in the second direction DR2 as illustrated in FIGS. 5 and 6, a length of the folding area FDA in the second direction DR2 may be greater than a length of the folding area FDA in the first direction DR1. In addition, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

Each of the display area DA and the non-display area NDA may overlap at least one of the folding area FDA, the first non-folding area NFA1, and the second non-folding area NFA2. It has been illustrated in FIGS. 5 and 6 that each of the display area DA and the non-display area NDA overlaps the folding area FDA, the first non-folding area NFA1, and the second non-folding area NFA2.

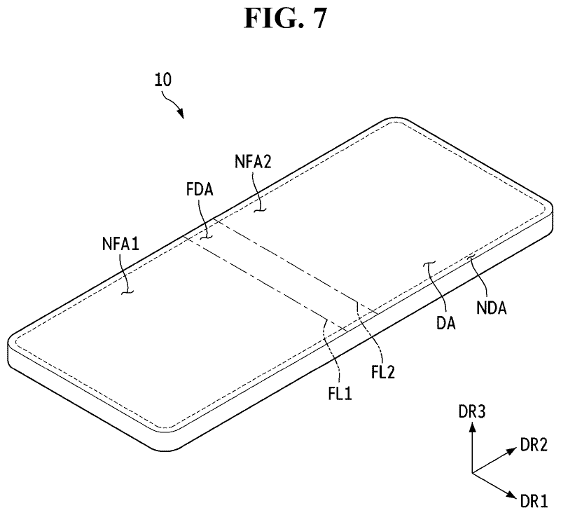

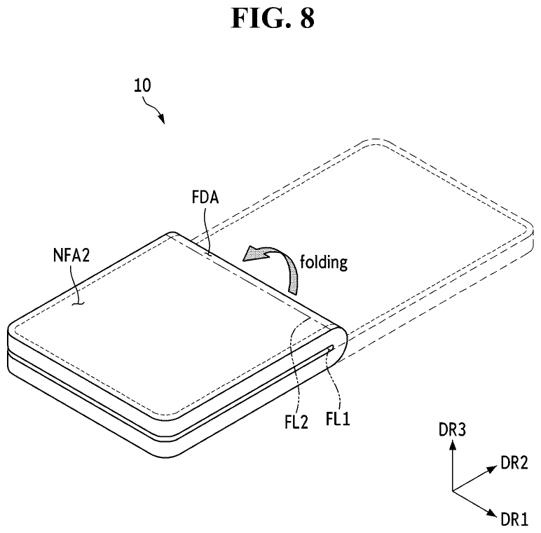

FIG. 7 is a perspective view illustrating another embodiment of an unfolded state of a display device. FIG. 8 is a perspective view illustrating another embodiment of a folded state of the display device.

Referring to FIGS. 7 and 8, a first state of a display device 10 that is not folded at folding lines FL1 and FL2 and is unfolded is illustrated in FIG. 7, and a second state of the display device 10 that is folded at the folding lines FL1 and FL2 is illustrated in FIG. 8.

Another embodiment of FIGS. 7 and 8 is different from another embodiment of FIGS. 5 and 6 in that the first folding line FL1 and the second folding line FL2 extend in the first direction DR1 and the display device 10 is folded in the second direction DR2, and thus, a length of the display device 10 in the second direction DR2 is reduced by approximately half. Therefore, in FIGS. 7 and 8, a description of contents overlapping those of another embodiment of FIGS. 5 and 6 will be omitted.

In the first state in which the display device 10 is unfolded, long sides of the display device 10 may extend along the second direction DR2, and short sides of the display device 10 may extend along the first direction DR1.

The first folding line FL1 and the second folding line FL2 may extend in the first direction DR1 as illustrated in FIGS. 7 and 8, and in this case, the display device 10 may be folded based on the first direction DR1.

The first non-folding area NFA1 may be disposed on one side, e.g., the lower side, of the folding area FDA. The second non-folding area NFA2 may be disposed on an opposite side, e.g., the upper side, of the folding area FDA. Here, the upper side may refer to one side in the second direction DR2, and the lower side may refer to an opposite side in the second direction DR2.

When the first folding line FL1 and the second folding line FL2 extend in the first direction DR1 as illustrated in FIGS. 7 and 8, a length of the folding area FDA in the first direction DR1 may be greater than a length of the folding area FDA in the second direction DR2. In addition, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

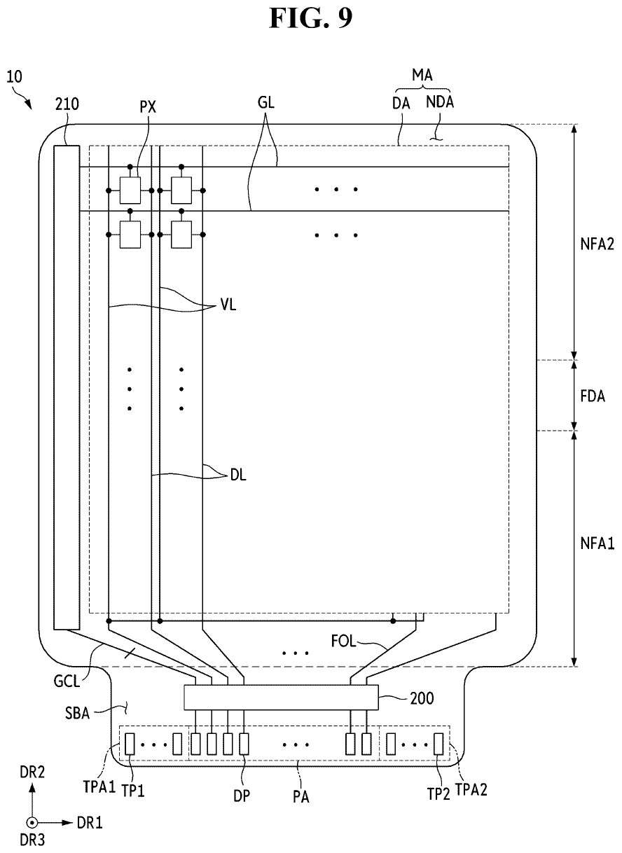

FIG. 9 is a plan view illustrating embodiments of the display device of FIGS. 5 to 8.

Referring to FIG. 9, the display device 10 in embodiments of FIGS. 5 to 8 may also include a main area MA and a sub-area SBA, similar to the display device 10 in an embodiment described with reference to FIG. 3, and the main area MA may include a display area DA and a non-display area NDA. Arrangements of the pixels PX and lines of the main area MA and the sub-area SBA has been described above, and thus, contents different from those described above will be mainly described.

The main area MA may include a folding area FDA and non-folding areas NFA1 and NFA2. The folding area FDA may be disposed approximately at the center of the main area MA in the first direction DR1 or the second direction DR2. A first non-folding area NFA1 and a second non-folding area NFA2 may be disposed on opposite sides of the folding area FDA in the main area MA. The folding area FDA and the non-folding areas NFA1 and NFA2 may overlap the display area DA and the non-display area NDA of the main area MA.

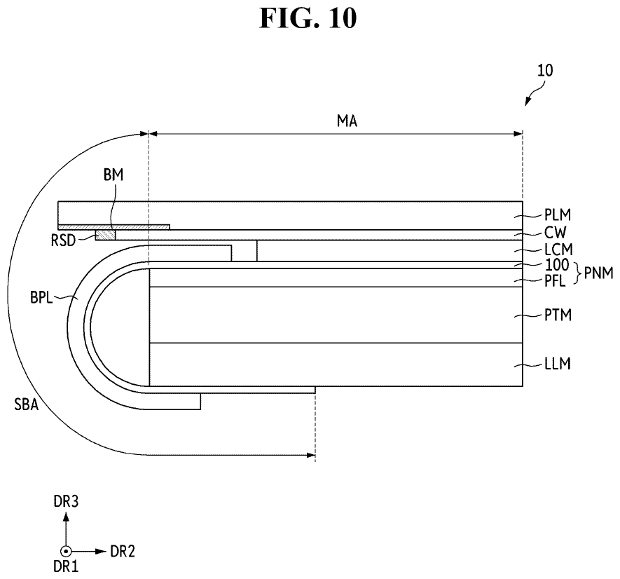

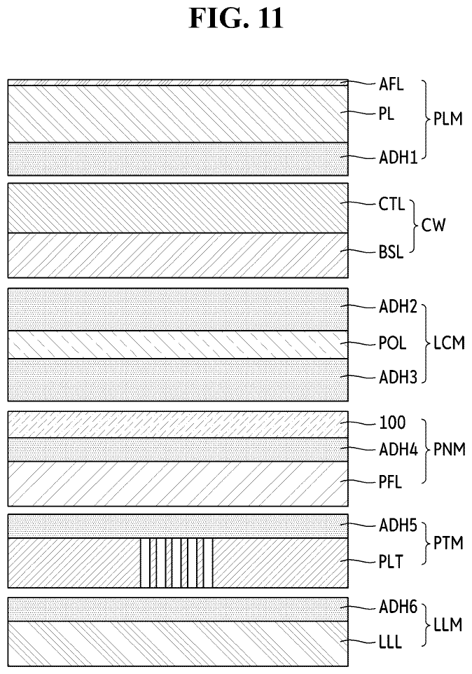

FIG. 10 is a schematic cross-sectional view illustrating embodiments of the display device of FIGS. 5 to 8. FIG. 11 is a detailed cross-sectional view illustrating the display device in embodiments of FIGS. 5 to 8.

Referring to FIGS. 10 and 11, the display device 10 may include a panel member PNM, an optical member LCM, a cover window CW, an upper protection member PLM, a panel support member PTM, and a lower functional member LLM.

The panel member PNM may include a display panel 100, a panel protection layer PFL, and a fourth adhesive layer ADH4.

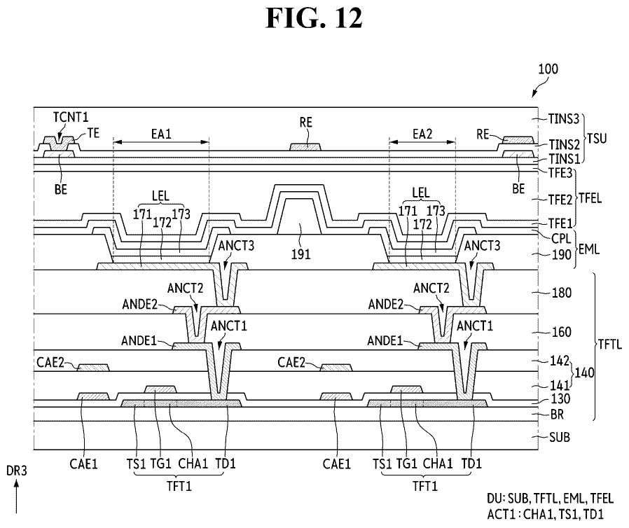

The display panel 100 may include a main area MA and a sub-area SBA, and may include a display layer DU (refer to FIG. 4) and a touch sensing layer TSU, similar to the display device 10 in an embodiment described above with reference to FIG. 4. The display panel 100 may be bent in the sub-area SBA. The display panel 100 will be described later with reference to FIG. 12.

The panel protection layer PFL may be disposed below the display panel 100. The panel protection layer PFL may server to support the display panel 100 and protect a lower surface of the display panel 100. The panel protection layer PFL may include or consist of plastic such as polyethylene terephthalate (“PET”) or polyimide.

The fourth adhesive layer ADH4 may be disposed between the display panel 100 and the panel protection layer PFL. The fourth adhesive layer ADH4 may adhere the display panel 100 and the panel protection layer PFL to each other. The fourth adhesive layer ADH4 may include a transparent adhesive such as a pressure sensitive adhesive (“PSA”) or an optically clear adhesive (“OCA”). The fourth adhesive layer ADH4 may include an acrylic adhesive material.

The optical member LCM may be disposed on the panel member PNM. The optical member LCM may include a polarizing layer POL, a second adhesive layer ADH2, and a third adhesive layer ADH3.

The polarizing layer POL may be disposed on the display panel 100 in order to prevent a phenomenon in which external light is reflected from the display panel 100 to deteriorate the visibility of an image displayed on the display panel 100. The polarizing layer POL may include a first base member, a linear polarizer, a phase retardation film such as a λ/4 plate (quarter-wave plate), and a second base member. The first base member, the phase retardation film, the linear polarizer, and the second base member of the polarizing layer POL may be sequentially stacked on the display panel 100.

The third adhesive layer ADH3 may be disposed between the panel member PNM and the polarizing layer POL. The third adhesive layer ADH3 may adhere the panel member PNM and the optical member LCM to each other. The third adhesive layer ADH3 may include a transparent adhesive such as a pressure sensitive adhesive (“PSA”) or an optically clear adhesive (“OCA”). The third adhesive layer ADH3 may include an acrylic adhesive material.

The second adhesive layer ADH2 may be disposed between the polarizing layer POL and the cover window CW. The second adhesive layer ADH2 may adhere the optical member LCM and the cover window CW to each other. The second adhesive layer ADH2 may include a transparent adhesive such as a pressure sensitive adhesive (“PSA”) or an optically clear adhesive (“OCA”). The second adhesive layer ADH2 may include an acrylic adhesive material.

The cover window CW may include a base layer BSL and a coating layer CTL. The base layer BSL may serve as a support layer for forming the coating layer CTL. In some embodiments, the base layer BSL may include plastic such as polyethylene terephthalate (“PET”) or polyimide.

The cover window CW may include a residual trace RSD. The residual trace RSD is described later with reference to FIGS. 16 to 18.

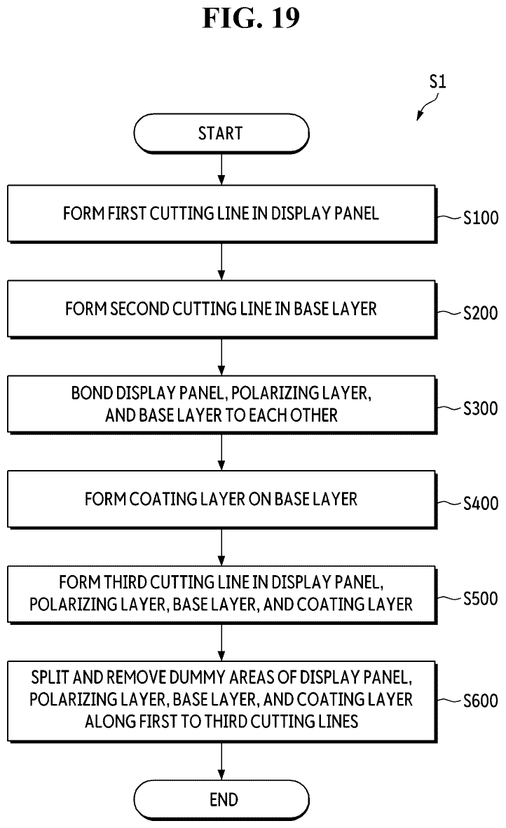

The coating layer CTL may include a polymer resin for improving surface quality of the display device 10. In an embodiment, the coating layer CTL may be formed by applying and curing a liquid resin to the base layer BSL, as described in a method (S1) for manufacturing a display device to be described later (refer to FIG. 19), for example. The coating layer CTL may planarize waviness or crease occurring in an underlying structure of the cover window CW to improve the surface quality of the display device 10.

The upper protection member PLM may be disposed on the cover window CW. The upper protection member PLM may include an upper protection layer PL, an anti-fingerprint layer AFL, and a first adhesive layer ADH1.

The upper protection layer PL may perform at least one of an anti-scattering function of the cover window CW an impact absorption function, an anti-scratch function, an anti-fingerprint function, an anti-glare function. In some embodiments, the upper protection layer PL may include plastic such as polyethylene terephthalate (“PET”) or polyimide.

The anti-fingerprint layer AFL may be disposed on an upper surface of the upper protection layer PL. The anti-fingerprint layer AFL may be formed through an anti-finger (“AF”) coating. In some embodiments, the anti-fingerprint layer AFL may further perform an anti-reflection function through an anti-reflection (“AR”) coating.

A first adhesive layer ADH1 may be disposed between the cover window CW and the upper protection layer PL. The first adhesive layer ADH1 may adhere the cover window CW and the upper protection member PLM to each other. The first adhesive layer ADH1 may include a transparent adhesive such as a pressure sensitive adhesive (“PSA”) or an optically clear adhesive (“OCA”). The first adhesive layer ADH1 may include an acrylic adhesive material.

In some embodiments, the upper protection member PLM may further include a light-blocking portion BM. The light-blocking portion BM may be disposed on the upper protection layer PL. The light-blocking portion BM may include a light-absorbing material. In an embodiment, the light-blocking portion BM may include an inorganic black pigment or an organic black pigment, for example. The inorganic black pigment may be carbon black, and the organic black pigment may include at least one of Lactam Black, Perylene Black, and Aniline Black, but the disclosure is not limited thereto.

It has been illustrated in FIG. 10 that the light-blocking portion BM is disposed only on one side surface of the upper protection member PLM, but the disclosure is not limited thereto. In an embodiment, just as the non-display area NDA surrounds the display area DA as illustrated in FIG. 9, the light-blocking portion BM may be disposed in the non-display area NDA so as to surround the display area DA, for example. That is, the light-blocking portion BM may surround an edge of the upper protection member PLM.

The light-blocking portion BM may overlap the residual trace RSD of the cover window CW in the third direction DR3. Accordingly, the residual trace RSD of the cover window CW may not be viewed from the outside by the light-blocking portion BM of the upper protection member PLM.

The panel support member PTM may be disposed beneath the panel member PNM. The panel support member PTM may include a panel support layer PLT and a fifth adhesive layer ADH5.

The panel support layer PLT may be a rigid member whose shape or volume does not easily change due to an external pressure. The panel support layer PLT is the rigid member whose shape or volume does not easily change due to the external pressure, and may thus support the display panel 100.

In an embodiment, the panel support layer PLT may include or consist of a polymer including carbon fiber or glass fiber. In this case, since the panel support layer PLT includes or consists of the polymer including the carbon fiber or the glass fiber, the panel support layer PLT may pass a magnetic field or an electromagnetic signal of a digitizer when the digitizer is included in the lower functional member LLM. Therefore, the panel support layer PLT capable of supporting the display panel 100 without lowering touch sensitivity of the digitizer may be provided.

In another embodiment, the panel support layer PLT may be a metal plate. In an embodiment, the panel support layer PLT is a metal plate, and may include or consist of metal or a metal alloy, for example. The panel support layer PLT may include copper (Cu), aluminum (Al), stainless steel (SUS), and/or alloys thereof, but is not limited thereto.

In another embodiment, the panel support layer PLT may include a glass material. In an embodiment, the panel support layer PLT may include an ultra-thin glass (“UTG”) having a thickness of 300 micrometers (μm) or less, for example.

The fifth adhesive layer ADH5 may be disposed between the panel member PNM and the panel support layer PLT. The fifth adhesive layer ADH5 may adhere the panel member PNM and the panel support member PTM to each other. The fifth adhesive layer ADH5 may include a transparent adhesive such as a pressure sensitive adhesive (“PSA”) or an optically clear adhesive (“OCA”). The fifth adhesive layer ADH5 may include an acrylic adhesive material.

The lower functional member LLM may be disposed beneath the panel support member PTM. The lower functional member LLM may include a lower functional layer LLL and a sixth adhesive layer ADH6.

The lower functional layer LLL may perform various functions by including one or more functional layers. In an embodiment, the lower functional layer LLL may include at least one of a light-blocking layer for absorbing light incident from the outside, a buffer layer for absorbing an external impact, and a heat dissipation layer for efficiently dissipating heat of the display panel 100, for example. In addition, the lower functional layer LLL may include a digitizer for detecting the approach or contact of an electronic pen such as a stylus pen supporting electromagnetic resonance (“EMR”). In addition, the lower functional layer LLL may include a waterproof and dustproof member for preventing permeation of moisture or dust.

The sixth adhesive layer ADH6 may be disposed between the panel support member PTM and the lower functional layer LLL. The sixth adhesive layer ADH6 may adhere the panel support member PTM and the lower functional member LLM to each other. The sixth adhesive layer ADH6 may include a transparent adhesive such as a pressure sensitive adhesive (“PSA”) or an optically clear adhesive (“OCA”). The sixth adhesive layer ADH6 may include an acrylic adhesive material.

The display device 10 may further include a bending protection layer BPL. The bending protection layer BPL may be disposed in a bending area of the sub-area SBA. The bending protection layer BPL may be a layer for protecting the thin film transistor layer TFTL (refer to FIG. 4) of the display panel 100 exposed to the outside. In addition, the bending protection layer BPL may protect the display panel 100 from tensile force or other external force that may be applied to the display panel 100 when the display device 10 is bent. The bending protection layer BPL may include or consist of an organic material such as an acrylic resin, an epoxy resin, a phenolic resin, a polyamide resin, or a polyimide resin.

FIG. 12 is a cross-sectional view illustrating an embodiment of a display panel.

Referring to FIG. 12, the display panel 100 may include a display layer DU and a touch sensing layer TSU. The display layer DU may include a substrate SUB, a thin film transistor layer TFTL, a light-emitting element layer EML, and a thin film encapsulation layer TFEL.

The substrate SUB may be a base substrate or a base member. The substrate SUB may be a flexible substrate that may be bent, folded, and rolled. In an embodiment, the substrate SUB may include a polymer resin such as polyimide (“PI”), but is not limited thereto. In another embodiment, the substrate SUB may include a glass material or a metal material, for example.

The thin film transistor layer TFTL may be disposed on the substrate SUB. The thin film transistor layer TFTL may include a barrier film BR, thin film transistors TFT1, first capacitor electrodes CAE1, second capacitor electrodes CAE2, first anode connection electrodes ANDE1, second anode connection electrodes ANDE2, a gate insulating film 130, a first inter-insulating film 141, a second inter-insulating film 142, a first planarization film 160, and a second planarization film 180. In an embodiment, the first inter-insulating film 141 and the second inter-insulating film 142 may be collectively referred to as an inter-insulating film 140.

The barrier film BR may be disposed on the substrate SUB. The barrier film BR is a film for protecting thin film transistors of the thin film transistor layer TFTL and light-emitting layers 172 of the light-emitting element layer EML from moisture permeating through the substrate SUB vulnerable to moisture permeation. The barrier film BR may include a plurality of inorganic films that are alternately stacked. In an embodiment, the barrier film BR may be formed as multiple films in which one or more inorganic films of a silicon nitride layer, a silicon oxynitride layer, a silicon oxide layer, a titanium oxide layer, and an aluminum oxide layer are alternately stacked, for example.

The thin film transistors TFT1 may be disposed on the barrier film BR. Active layers ACT1 of the thin film transistors TFT1 may be disposed on the barrier film BR. The active layer ACT1 of the thin film transistor TFT1 may include polycrystalline silicon, single crystal silicon, low-temperature polycrystalline silicon, amorphous silicon, or an oxide semiconductor.

The active layer ACT1 may include a channel region CHA1, a source region TS1, and a drain region TD1. The channel region CHA1 may be a region overlapping a gate electrode TG1 in the third direction DR3, which is a thickness direction of the substrate SUB. The source region TS1 may be disposed on one side of the channel region CHA1, and the drain region TD1 may be disposed on an opposite side of the channel region CHA1. The source region TS1 and the drain region TD1 may be regions that do not overlap the gate electrode TG1 in the third direction DR3. The source region TS1 and the drain region TD1 may be regions having conductivity by doping a silicon semiconductor or an oxide semiconductor with ions or impurities.

The gate insulating film 130 may be disposed on the active layers ACT1 of the thin film transistors TFT1. The gate insulating film 130 may be formed as an inorganic film such as a silicon nitride layer, a silicon oxynitride layer, a silicon oxide layer, a titanium oxide layer, or an aluminum oxide layer.

The gate electrodes TG1 of the thin film transistors TFT1 and the first capacitor electrodes CAE1 may be disposed on the gate insulating film 130. The gate electrode TG1 may overlap the channel region CHA1 in the third direction DR3. It has been illustrated in FIG. 12 that the gate electrode TG1 and the first capacitor electrode CAE1 are spaced apart from each other, but the gate electrode TG1 and the first capacitor electrode CAE1 may also be connected to and formed integrally with each other. Each of the gate electrode TG1 and the first capacitor electrode CAE1 may be formed as a single layer or multiple layers including or consisting of any one of molybdenum (Mo), aluminum (Al), chromium (Cr), gold (Au), titanium (Ti), nickel (Ni), neodymium (Nd), and copper (Cu), or alloys thereof.

The first inter-insulating film 141 may be disposed on the gate electrodes TG1 of the thin film transistors TFT1 and the first capacitor electrodes CAE1. The first inter-insulating film 141 may be formed as an inorganic film such as a silicon nitride layer, a silicon oxynitride layer, a silicon oxide layer, a titanium oxide layer, or an aluminum oxide layer. The first inter-insulating film 141 may be formed as a plurality of inorganic films.

The second capacitor electrodes CAE2 may be disposed on the first inter-insulating film 141. The second capacitor electrode CAE2 may overlap the first capacitor electrode CAE1 in the third direction DR3. In addition, when the gate electrode TG1 and the first capacitor electrode CAE1 are formed integrally with each other, the second capacitor electrode CAE2 may overlap the gate electrode TG1 in the third direction DR3. Since the first inter-insulating film 141 has a selected dielectric constant, a capacitor may be formed by the first capacitor electrode CAE1, the second capacitor electrode CAE2, and the first inter-insulating film 141 disposed between the first capacitor electrode CAE1 and the second capacitor electrode CAE2. The second capacitor electrode CAE2 may be formed as a single layer or multiple layers including or consisting of any one of molybdenum (Mo), aluminum (Al), chromium (Cr), gold (Au), titanium (Ti), nickel (Ni), neodymium (Nd), and copper (Cu), or alloys thereof.

The second inter-insulating film 142 may be disposed on the second capacitor electrodes CAE2. The second inter-insulating film 142 may be formed as an inorganic film such as a silicon nitride layer, a silicon oxynitride layer, a silicon oxide layer, a titanium oxide layer, or an aluminum oxide layer. The second inter-insulating film 142 may be formed as a plurality of inorganic films.

The first anode connection electrodes ANDE1 may be disposed on the second inter-insulating film 142. The first anode connection electrode ANDE1 may be connected to the drain region TD1 of the thin film transistor TFT1 through a first connection contact hole ANCT1 penetrating through the gate insulating film 130, the first inter-insulating film 141, and the second inter-insulating film 142. The first anode connection electrode ANDE1 may be formed as a single layer or multiple layers including or consisting of any one of molybdenum (Mo), aluminum (Al), chromium (Cr), gold (Au), titanium (Ti), nickel (Ni), neodymium (Nd), and copper (Cu), or alloys thereof.

The first planarization film 160 for planarizing a step due to the thin film transistors TFT1 may be disposed on the first anode connection electrodes ANDE1. The first planarization film 160 may be formed as an organic film including or consisting of an acrylic resin, an epoxy resin, a phenolic resin, a polyamide resin, a polyimide resin, or the like.

The second anode connection electrodes ANDE2 may be disposed on the first planarization film 160. The second anode connection electrode ANDE2 may be connected to the first anode connection electrode ANDE1 through a second connection contact hole ANCT2 penetrating through the first planarization film 160. The second anode connection electrode ANDE2 may be formed as a single layer or multiple layers including or consisting of any one of molybdenum (Mo), aluminum (Al), chromium (Cr), gold (Au), titanium (Ti), nickel (Ni), neodymium (Nd), and copper (Cu), or alloys thereof.

The second planarization film 180 may be disposed on the second anode connection electrodes ANDE2. The second planarization film 180 may be formed as an organic film including or consisting of an acrylic resin, an epoxy resin, a phenolic resin, a polyamide resin, a polyimide resin, or the like.

The light-emitting element layer EML including light-emitting elements LEL and a bank 190 may be disposed on the second planarization film 180. Each of the light-emitting elements LEL includes a pixel electrode 171, a light-emitting layer 172, and a common electrode 173.

The pixel electrode 171 may be disposed on the second planarization film 180. The pixel electrode 171 may be connected to the second anode connection electrode ANDE2 through a third connection contact hole ANCT3 penetrating through the second planarization film 180.

In a top emission structure in which light is emitted toward the common electrode 173 based on the light-emitting layer 172, the pixel electrode 171 may include or consist of a metal material having relatively high reflectivity, such as a stacked structure (Ti/Al/Ti) of aluminum (Al) and titanium (Ti), a stacked structure (ITO/Al/ITO) of aluminum (Al) and indium tin oxide (“ITO”), a stacked structure (ITO/Ag/ITO) of silver (Ag) and ITO, an APC alloy, and a stacked structure (ITO/APC/ITO) of an APC alloy and ITO. The APC alloy is an alloy of silver (Ag), palladium (Pd), and copper (Cu).

The bank 190 may partition the pixel electrodes 171 on the second planarization film 180 in order to define light-emitting portions EA1 and EA2. The bank 190 may cover edges of the pixel electrode 171. The bank 190 may be formed as an organic film including or consisting of an acrylic resin, an epoxy resin, a phenolic resin, a polyamide resin, a polyimide resin, or the like.

Each of a first light-emitting portion EA1 and a second light-emitting portion EA2 refers to each area where the pixel electrode 171, the light-emitting layer 172, and the common electrode 173 are sequentially stacked and holes from the pixel electrode 171 and electrons from the common electrode 173 are recombined with each other in the light-emitting layer 172 to emit light.

The light-emitting layer 172 may be disposed on the pixel electrode 171 and the bank 190. The light-emitting layer 172 may include an organic material to emit light of a selected color. In an embodiment, the light-emitting layer 172 may include a hole transporting layer, an organic material layer, and an electron transporting layer, for example.

The common electrode 173 may be disposed on the light-emitting layer 172. The common electrode 173 may cover the light-emitting layer 172. The common electrode 173 may be a common layer formed in common in the first light-emitting portion EA1 and the second light-emitting portion EA2.

In the top emission structure, the common electrode 173 may include or consist of a transparent conductive material (“TCO”) such as ITO or indium zinc oxide (“IZO”) capable of transmitting light or a semi-transmissive conductive material such as magnesium (Mg), silver (Ag), or an alloy of magnesium (Mg) and silver (Ag). When the common electrode 173 includes or consists of the semi-transmissive conductive material, light emission efficiency may be increased by a micro cavity.

A spacer 191 may be disposed on the bank 190. The spacer 191 may serve to support a mask during a manufacturing process of manufacturing the light-emitting layer 172. The spacer 191 may be formed as an organic film including or consisting of an acrylic resin, an epoxy resin, a phenolic resin, a polyamide resin, a polyimide resin, or the like.

In some embodiments, the display panel 100 may further include a capping layer CPL disposed on the common electrode 173. The capping layer CPL may include an inorganic material. In an embodiment, the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride, for example.

The thin film encapsulation layer TFEL may be disposed on the common electrode 173. The thin film encapsulation layer TFEL may include at least one inorganic film in order to prevent oxygen or moisture from permeating into the light-emitting element layer EML. In addition, the thin film encapsulation layer TFEL may include at least one organic film in order to protect the light-emitting element layer EML from foreign substances such as dust. In an embodiment, the thin film encapsulation layer TFEL may include a first encapsulation inorganic film TFE1, an encapsulation organic film TFE2, and a second encapsulation inorganic film TFE3, for example.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. Each of the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film including or consisting of an acrylic resin, an epoxy resin, a phenolic resin, a polyamide resin, a polyimide resin, or the like.

The touch sensing layer TSU may be disposed on the thin film encapsulation layer TFEL. The touch sensing layer TSU includes a first touch insulating film TINS1, connection electrodes BE, a second touch insulating film TINS2, driving electrodes TE, sensing electrodes RE, and a third touch insulating film TINS3.

The first touch insulating film TINS1 may be disposed on the thin film encapsulation layer TFEL. The first touch insulating film TINS1 may be formed as an inorganic film such as a silicon nitride layer, a silicon oxynitride layer, a silicon oxide layer, a titanium oxide layer, or an aluminum oxide layer.

The connection electrodes BE may be disposed on the first touch insulating film TINS1. The connection electrode BE may be formed as a single layer or multiple layers including or consisting of any one of molybdenum (Mo), aluminum (Al), chromium (Cr), gold (Au), titanium (Ti), nickel (Ni), neodymium (Nd), and copper (Cu), or alloys thereof.

The second touch insulating film TINS2 may be disposed on the connection electrodes BE. The second touch insulating film TINS2 may be formed as an inorganic film such as a silicon nitride layer, a silicon oxynitride layer, a silicon oxide layer, a titanium oxide layer, or an aluminum oxide layer. In an alternative embodiment, the second touch insulating film TINS2 may be formed as an organic film including or consisting of an acrylic resin, an epoxy resin, a phenolic resin, a polyamide resin, a polyimide resin, or the like.

The driving electrodes TE and the sensing electrodes RE may be disposed on the second touch insulating film TINS2. Each of the driving electrodes TE and the sensing electrodes RE may be formed as a single layer or multiple layers including or consisting of any one of molybdenum (Mo), aluminum (Al), chromium (Cr), gold (Au), titanium (Ti), nickel (Ni), neodymium (Nd), and copper (Cu), or alloys thereof.

The driving electrode TE and the sensing electrode RE may overlap the connection electrodes BE in the third direction DR3. The driving electrode TE may be connected to the connection electrode BE through a touch contact hole TCNT1 penetrating through the second touch insulating film TINS2.

The third touch insulating film TINS3 may be formed on the driving electrodes TE and the sensing electrodes RE. The third touch insulating film TINS3 may serve to planarize a step formed due to the driving electrodes TE, the sensing electrodes RE, and the connection electrodes BE. The third touch insulating film TINS3 may be formed as an organic film including or consisting of an acrylic resin, an epoxy resin, a phenolic resin, a polyamide resin, a polyimide resin, or the like.

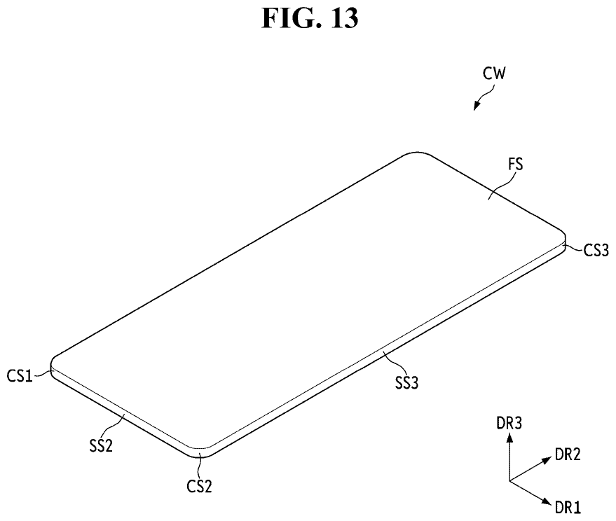

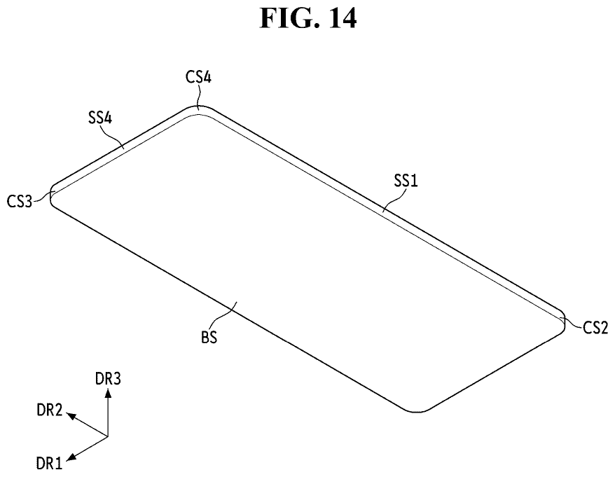

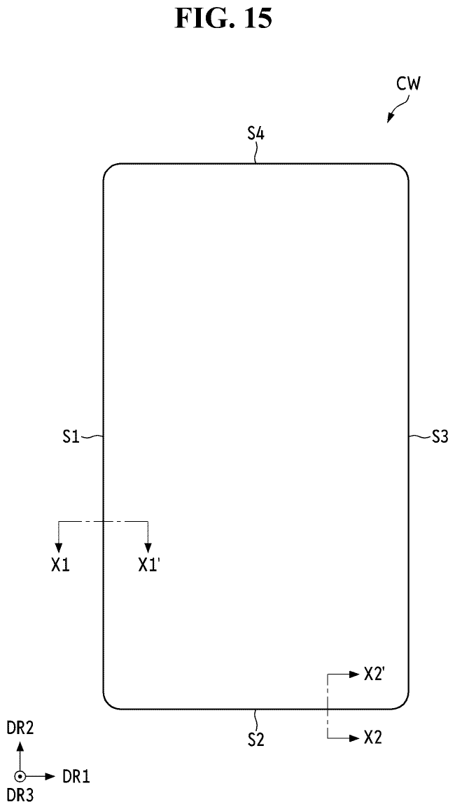

FIG. 13 is a front perspective view illustrating an embodiment of a cover window. FIG. 14 is a back perspective view illustrating an embodiment of the cover window. FIG. 15 is a plan view illustrating an embodiment of the cover window.

Referring to FIGS. 13 to 15, the cover window CW includes a front surface FS, a back surface BS, first to fourth side surfaces SS1, SS2, SS3, and SS4, and first to fourth corners CS1, CS2, CS3, and CS4.

The front surface FS may have short sides in the first direction DR1 and long sides in the second direction DR2. A corner where the short side in the first direction DR1 and the long side in the second direction DR2 meet in the front surface FS may be rounded with a selected radius of curvature or right-angled. The front surface FS may be flatly formed or may include a curved portion having a selected radius of curvature.

The first side surface SS1 may extend from a first side S1 of the front surface FS, and the first side S1 of the front surface FS may be the left side of the front surface FS. The second side surface SS2 may extend from a second side S2 of the front surface FS, and the second side S2 of the front surface FS may be the lower side of the front surface FS. The third side surface SS3 may extend from a third side S3 of the front surface FS, and the third side S3 of the front surface FS may be the right side of the front surface FS. The fourth side surface SS4 may extend from a fourth side S4 of the front surface FS, and the fourth side S4 of the front surface FS may be the upper side of the front surface FS.

In some embodiments, the second side surface SS2 may be a side surface next (adjacent) to the sub-area SBA (refer to FIGS. 3 and 9) described with reference to FIGS. 3 and 9.

The first corner CS1 may be a corner side surface disposed between the first side surface SS1 and the second side surface SS2. The second corner CS2 may be a corner side surface disposed between the second side surface SS2 and the third side surface SS3. The third corner CS3 may be a corner side surface disposed between the third side surface SS3 and the fourth side surface SS4. The fourth corner CS4 may be a corner side surface disposed between the first side surface SS1 and the fourth side surface SS4.

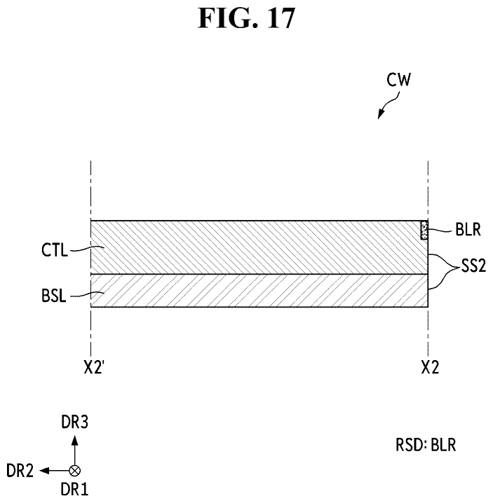

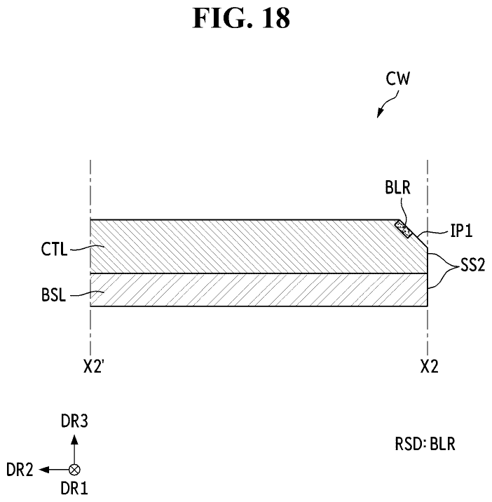

FIG. 16 is a cross-sectional view taken along line X1-X1′ of FIG. 15. FIG. 17 is a cross-sectional view illustrating an embodiment of a cross section taken along line X2-X2′ of FIG. 15. FIG. 18 is a cross-sectional view illustrating another embodiment of a cross section taken along line X2-X2′ of FIG. 15.

FIG. 16 is a cross-sectional view illustrating the first side surface SS1 of the cover window CW. The third side surface SS3 and the fourth side surface SS4 of the cover window CW may have substantially the same shapes as the first side surface SS1 except for directions thereof, and only the first side surface SS1 is thus described. FIGS. 17 and 18 are cross-sectional views illustrating the second side surface SS2 of the cover window CW. The second side surface SS2 of the cover window CW has a different shape from the first side surface SS1, and is thus described separately from the first side surface SS1.

Referring to FIGS. 16 to 18 in addition to FIGS. 4, 10, and 13 to 15, the cover window CW may include the first side surface SS1 and the second side surface SS2. As illustrated in FIGS. 16 and 17, the first side surface SS1 and the second side surface SS2 may be substantially vertical surfaces extending in the third direction DR3. That is, a side surface of the base layer BSL and the side of the coating layer CTL may be substantially vertical surfaces extending in the third direction DR3.

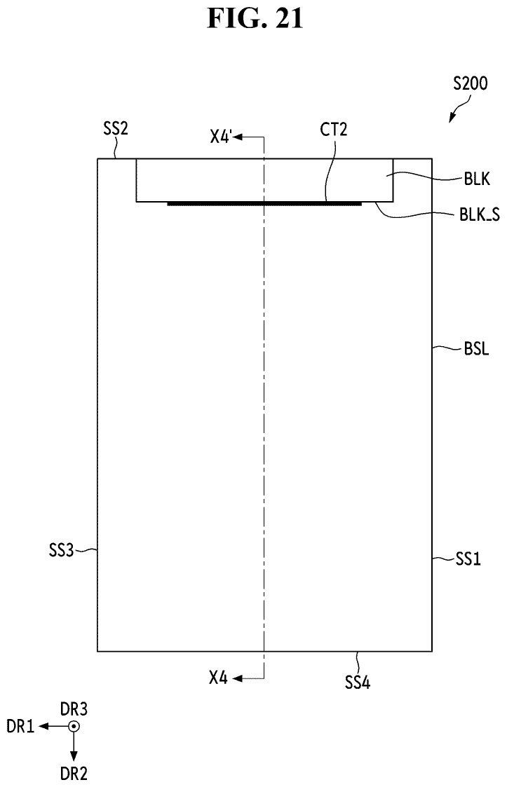

In some embodiments, as illustrated in FIG. 18, the cover window CW may further include a chamfered surface IP1. The chamfered surface IP1 may be disposed between an upper surface and a side surface of the coating layer CTL. The chamfered surface IP1 may extend in a diagonal direction defined by the second direction DR2 and the third direction DR3. The chamfered surface IP1 may be formed by a protrusion portion BLK_P of a shape control block BLK (refer to FIG. 21) of a method S1 (refer to FIG. 19) for manufacturing a display device to be described later.

The cover window CW may include residual traces RSD formed on a side surface thereof by a cutting process or a separation process for forming a shape of the cover window CW. The residual trace RSD may include a first residual trace HAZ1 and a second residual trace HAZ2 disposed on the first side surface SS1 of the cover window CW and a third residual trace BLR disposed on the second side surface SS2 or the chamfered surface IP1 of the cover window CW.

The first residual trace HAZ1 may be disposed on the side surface of the base layer BSL, and the second residual trace HAZ2 may be disposed on the side surface of the coating layer CTL. The first residual trace HAZ1 and the second residual trace HAZ2 may be formed by a laser cutting process of a method S1 (refer to FIG. 19) for manufacturing a display device to be described later.

The first residual trace HAZ1 and the second residual trace HAZ2 may be heat-affected zones (“HAZs”) formed by local heat of a laser beam. The first residual trace HAZ1 and the second residual trace HAZ2 may be zones where properties of materials included in the base layer BSL and the coating layer CTL are changed due to a local relatively high temperature state caused by irradiation of the laser beam.

In an embodiment, physical, chemical, structural, and optical characteristics of the first residual trace HAZ1 may be different from physical, chemical, structural, and optical characteristics of remaining (the other) portions of the base layer BSL excluding the first residual trace HAZ1, and physical, chemical, structural, and optical characteristics of the second residual trace HAZ2 may be different from physical, chemical, structural, and optical characteristics of remaining (the other) portions of the coating layer CTL excluding the second residual trace HAZ2, for example. When the materials included in the base layer BSL and the coating layer CTL are different from each other, physical, chemical, structural, and optical characteristics of the first residual trace HAZ1 and the second residual trace HAZ2 may be different from each other.

The third residual trace BLR may be disposed on the side surface of the coating layer CTL or the chamfered surface IP1 in the second side surface SS2. The third residual trace BLR may be disposed on a portion of the side surface of the coating layer CTL next (adjacent) to the upper surface of the coating layer CTL or disposed on a portion of the chamfered surface IP1 next (adjacent) to the upper surface of the coating layer CTL. The third residual trace BLR may be formed by a shape processing process (or a splitting process) of a method S1 (refer to FIG. 19) for manufacturing a display device to be described later.

The third residual trace BLR may be a burr formed when the coating layer CTL is split by physical pressing force. In an embodiment, the third residual trace BLR may be a fine projection formed in a splitting process of the coating layer CTL, for example. It has been illustrated in FIGS. 17 and 18 that the third residual trace BLR is disposed inside the second side surface SS2 or the chamfered surface IP1, but the disclosure is not limited thereto. Since the third residual trace BLR is the fine projection, the third residual trace BLR may protrude from the second side surface SS2 or the chamfered surface IP1 or may be recessed from the second side surface SS2 or the chamfered surface IP1. That is, the third residual trace BLR may be a fine projection (or a burr) formed on the second side surface SS2 and the chamfered surface IP1 or in the second side surface SS2 and the chamfered surface IP1 itself.

The third residual trace BLR may be formed in a process of breaking the coating layer CTL having a relatively small thickness with physical pressing force in the shape processing process (or the splitting process) of a method S1 (refer to FIG. 19) for manufacturing a display device to be described later.

In the display device 10 in the illustrated embodiment, the first residual trace HAZ1, the second residual trace HAZ2, and the third residual trace BLR may overlap the light-blocking portion BM of the upper protection layer PL or the light-blocking portion BM of the upper protection member PLM in the third direction DR3. Accordingly, as described above with reference to FIGS. 4 and 10, the residual trace RSD of the cover window CW may not be viewed from the outside by the light-blocking portion BM of the upper protection layer PL or the light-blocking portion BM of the upper protection member PLM.

Hereinafter, a method for manufacturing a display device in an embodiment will be described.

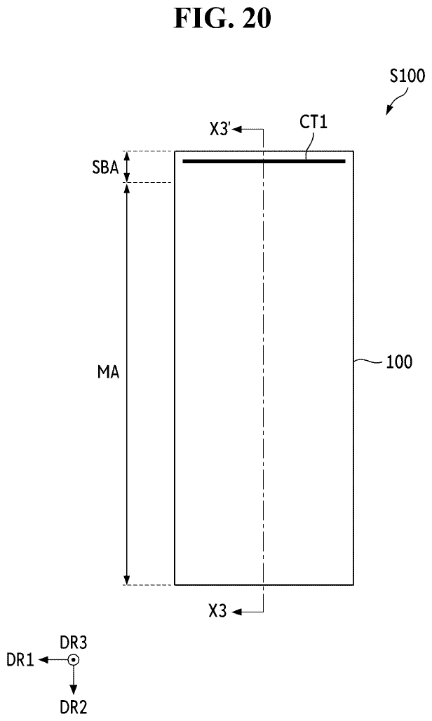

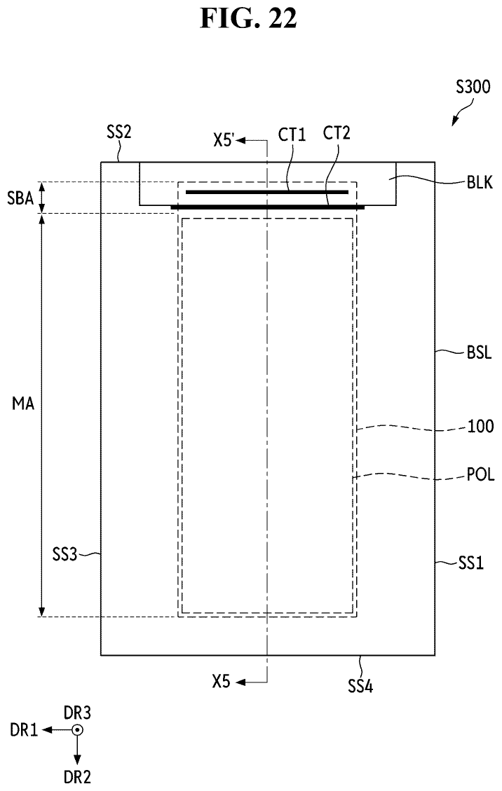

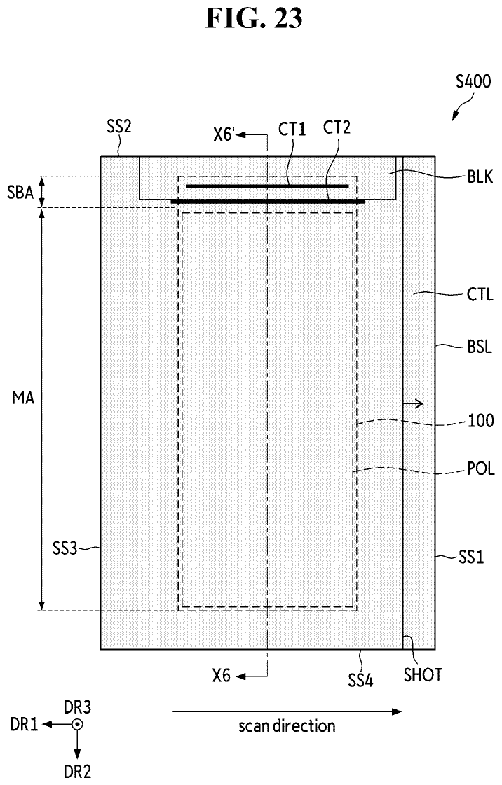

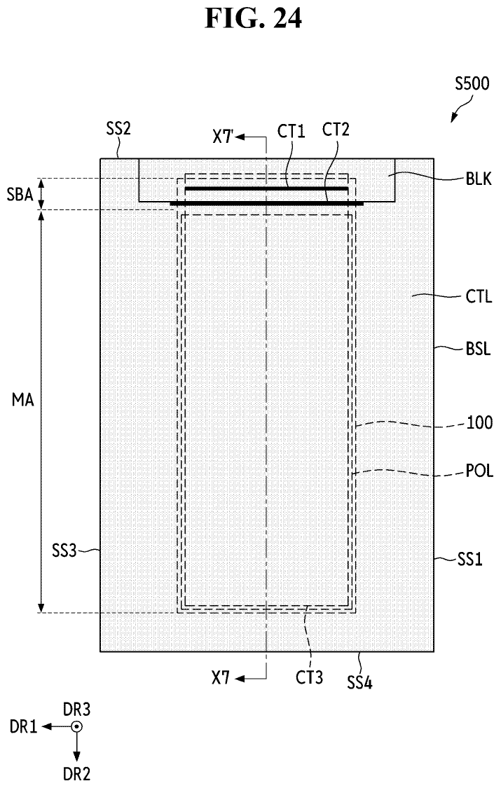

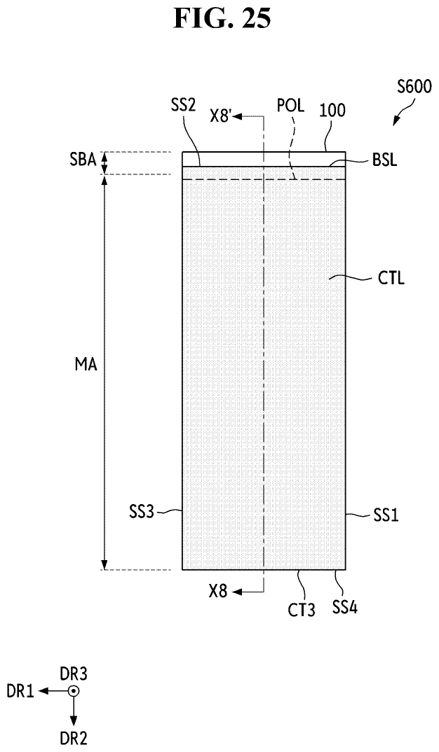

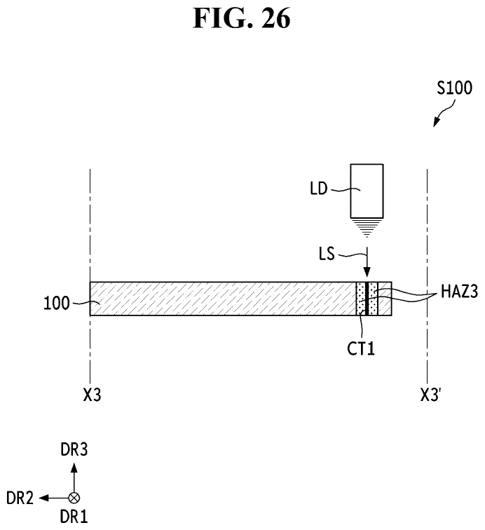

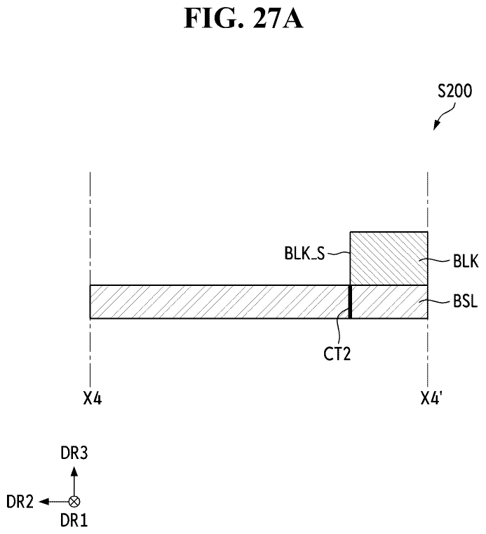

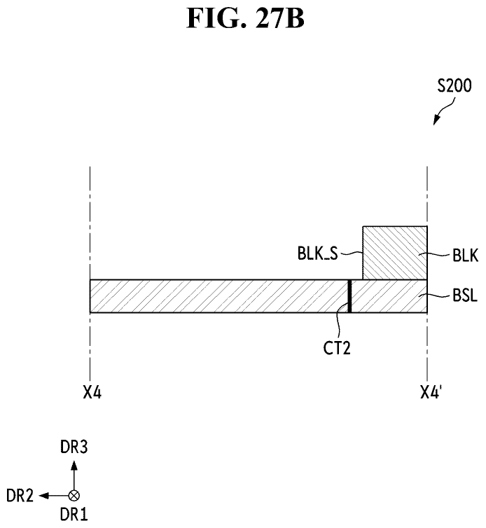

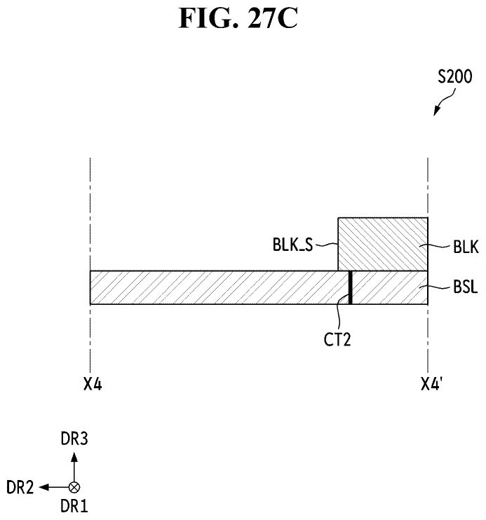

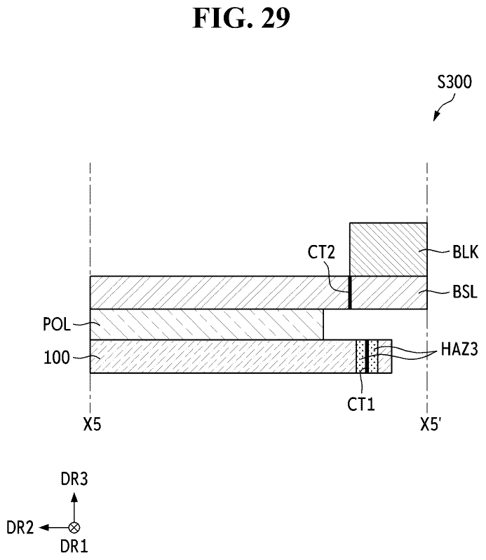

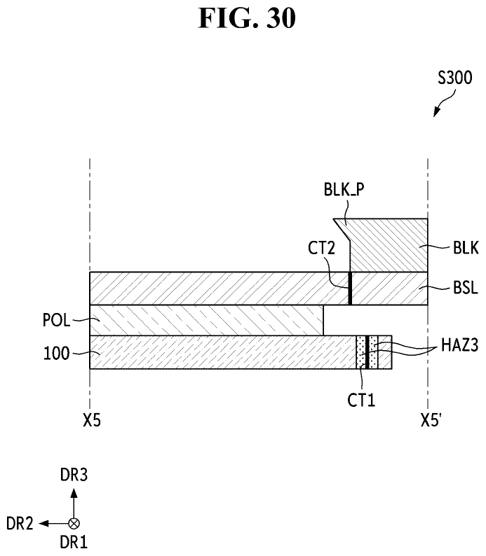

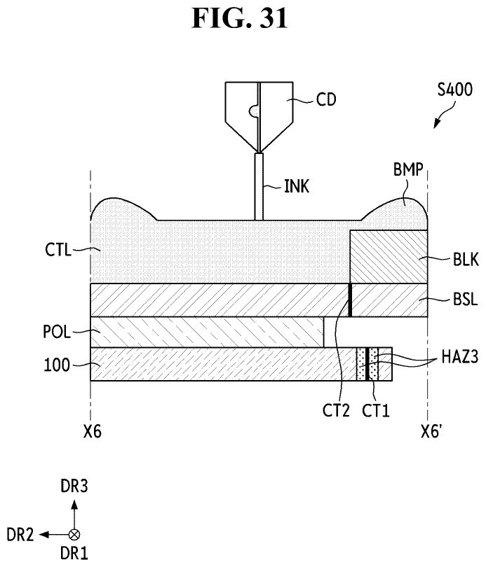

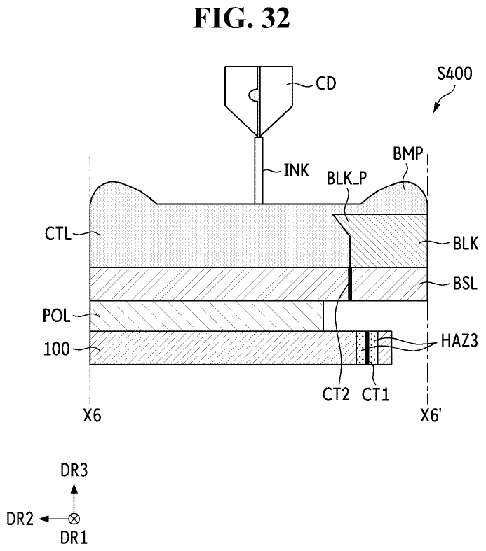

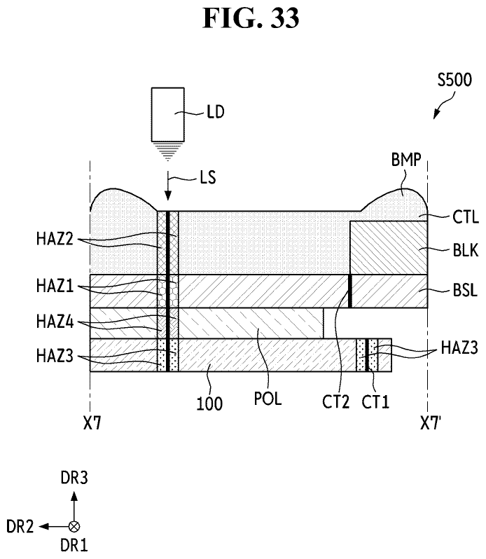

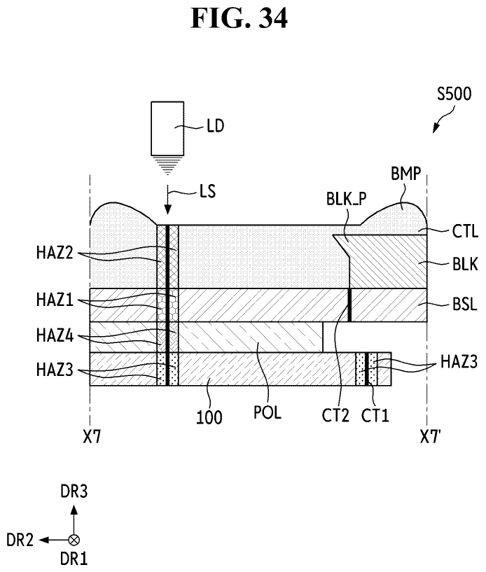

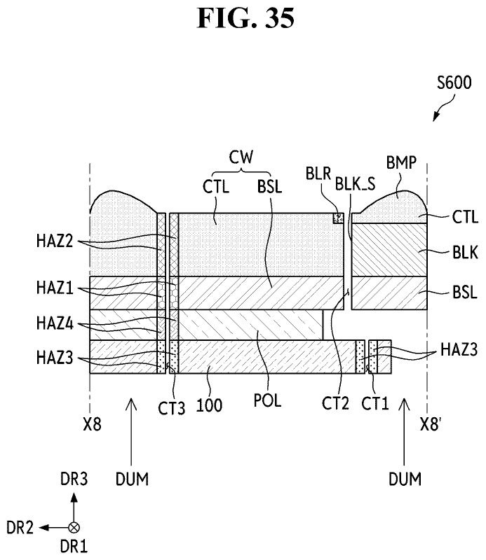

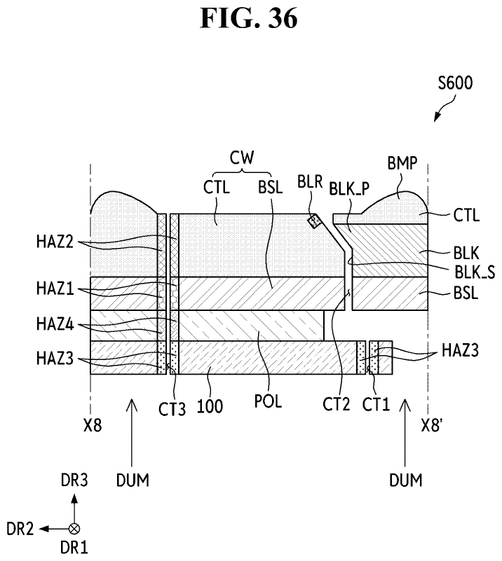

FIG. 19 is a flowchart illustrating an embodiment of a method for manufacturing the display device. FIG. 20 is a plan view illustrating the operation S100 of FIG. 19. FIG. 21 is a plan view illustrating the operation S200 of FIG. 19. FIG. 22 is a plan view illustrating the operation S300 of FIG. 19. FIG. 23 is a plan view illustrating the operation S400 of FIG. 19. FIG. 24 is a plan view illustrating the operation S500 of FIG. 19. FIG. 25 is a plan view illustrating the operation S600 of FIG. 19. FIG. 26 is a cross-sectional view illustrating the operation S100 of FIG. 19. FIGS. 27A to 27C are cross-sectional views illustrating several embodiments of the operation S200 of FIG. 19. FIG. 29 is a cross-sectional view illustrating an embodiment of the operation S300 of FIG. 19. FIG. 30 is a cross-sectional view illustrating another embodiment of the operation S300 of FIG. 19. FIG. 31 is a cross-sectional view illustrating an embodiment of the operation S400 of FIG. 19. FIG. 32 is a cross-sectional view illustrating another embodiment of the operation S400 of FIG. 19. FIG. 33 is a cross-sectional view illustrating an embodiment of the operation S500 of FIG. 19. FIG. 34 is a cross-sectional view illustrating another embodiment of the operation S500 of FIG. 19. FIG. 35 is a cross-sectional view illustrating an embodiment of the operation S600 of FIG. 19. FIG. 36 is a cross-sectional view illustrating another embodiment of the operation S600 of FIG. 19.

Referring to FIGS. 19 to 36, a method S1 for manufacturing the display device in an embodiment may include forming a first cutting line in the display panel (S100), forming a second cutting line in the base layer (S200), bonding the display panel, the polarizing layer, and the base layer to each other (S300), forming the coating layer on the base layer (S400), forming a third cutting line in the display panel, the polarizing layer, the base layer, and the coating layer (S500), and splitting and removing dummy areas of the display panel, the polarizing layer, the base layer, and the coating layer along the first to third cutting lines (S600).

First, as illustrated in FIGS. 20 and 26, the first cutting line CT1 may be formed in the display panel 100 (refer to the operation S100 of FIG. 19).

The first cutting line CT1 may be a hole penetrating through the display panel 100 in a third direction DR3. The first cutting line CT1 may extend in the first direction DR1. The first cutting line CT1 may be next (adjacent) to the sub-area SBA of the display panel 100. The first cutting line CT1 may be spaced apart from a side of the display panel 100 next (adjacent) to the sub-area SBA among sides of the display panel 100 in the second direction DR2.

A length of the first cutting line CT1 in the first direction DR1 may be smaller than a length of the display panel 100 in the first direction DR1. Accordingly, opposite ends of the first cutting line CT1 in the first direction DR1 may be spaced apart from opposite ends of the display panel 100 in the first direction DR1.

The first cutting line CT1 may be formed by a laser processing device LD. The laser processing device LD may form the first cutting line CT1 by irradiating the display panel 100 with a laser beam LS.

A fourth residual trace HAZ3 may be formed around the first cutting line CT1 by heat energy of the laser beam LS. The fourth residual trace HAZ3 may surround the first cutting line CT1. In an embodiment, the fourth residual trace HAZ3 may be a HAZ formed by local heat of the laser beam, for example. The fourth residual trace HAZ3 may be a zone where properties of a material included in the display panel 100 are changed due to a local relatively high temperature state caused by the irradiation of the laser beam LS.

In an embodiment, physical, chemical, structural, and optical characteristics of the fourth residual trace HAZ3 may be different from physical, chemical, structural, and optical characteristics of remaining (the other) portions of the display panel 100 excluding the fourth residual trace HAZ3, for example.

Next, as illustrated in FIGS. 21, 27A to 27C, and 28, the second cutting line CT2 may be formed in the base layer BSL (refer to the operation S200 of FIG. 19).

The base layer BSL may include a shape control block BLK. The shape control block BLK may prevent overflow of ink INK in a coating process to be described later, and may control a shape of the coating layer CTL. In some embodiments, the shape control block BLK may include the same material as that of the base layer BSL. In an embodiment, the shape control block BLK may include plastic such as polyethylene terephthalate (“PET”) or polyimide, for example. However, the disclosure is not limited thereto, and the shape control block BLK may include a different material from the base layer BSL.

The shape control block BLK may be provided separately from the base layer BSL and bonded to the base layer BSL. In an alternative embodiment, the shape control block BLK may be included in the base layer BSL itself to constitute a single component. In an embodiment, the shape control block BLK and the base layer BSL may be physically manufactured as a single component during a manufacturing process, for example.

The shape control block BLK may extend in the first direction DR1. The shape control block BLK may be next (adjacent) to the second side surface SS2.

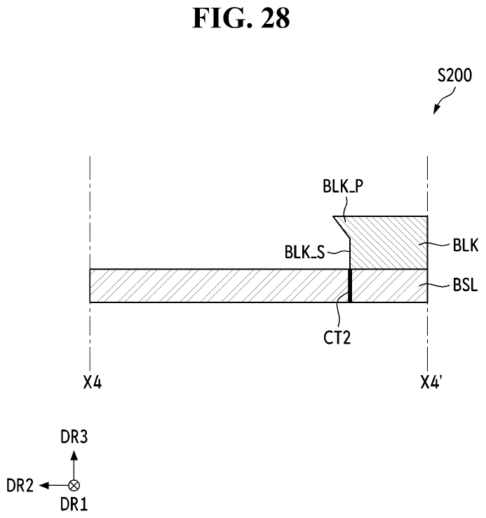

In some embodiments, as illustrated in FIGS. 27A to 27C, one side surface BLK_S of the shape control block BLK may be a substantially vertical surface extending in the third direction DR3. In another embodiment, as illustrated in FIG. 28, the shape control block BLK may include a protrusion portion BLK_P. The protrusion portion BLK_P may be a portion protruding from one side surface BLK_S of the shape control block BLK toward the second direction DR2. The shape control block BLK includes the protrusion portion BLK_P, and thus, the coating layer CTL may be easily split even with relatively small force in a splitting process of the coating layer CTL to be described later. When the shape control block BLK includes the protrusion portion BLK_P, the coating layer CTL may include the chamfered surface IP1, as described above with reference to FIG. 18.

The second cutting line CT2 may extend in the first direction DR1. The second cutting line CT2 may be next (adjacent) to the second side surface SS2. The second cutting line CT2 may be spaced apart from the second side surface SS2 in the second direction DR2.

The second cutting line CT2 may be a hole penetrating through the base layer BSL. In some embodiments, the second cutting line CT2 may be formed by penetrating through and cutting the base layer BSL using a tool such as a blade. In this case, although not illustrated in FIGS. 21, 27A to 27C, and 28, a residual trace such as a burr may remain around the second cutting line CT2. In another embodiment, the second cutting line CT2 may be formed by penetrating through and cutting the base layer BSL using a laser beam. In this case, although not illustrated in FIGS. 21, 27A to 27C, and 28, a residual trace such as a HAZ may remain around the second cutting line CT2.

A length of the second cutting line CT2 in the first direction DR1 may be smaller than a length of the base layer BSL in the first direction DR1. Accordingly, opposite ends of the second cutting line CT2 in the first direction DR1 may be spaced apart from opposite ends of the base layer BSL in the first direction DR1.

The second cutting line CT2 may be next (adjacent) to one side surface BLK_S of the shape control block BLK. In an embodiment, the second cutting line CT2 may overlap one side surface BLK_S of the shape control block BLK in the third direction DR3, as illustrated in FIGS. 27A and 28, for example.

However, the disclosure is not limited thereto, and the second cutting line CT2 may also be shifted from one side surface BLK_S of the shape control block BLK to one side or an opposite side in the second direction DR2, as illustrated in FIGS. 27B and 27C. When the second cutting line CT2 is shifted from one side surface BLK_S of the shape control block BLK to one side in the second direction DR2 as illustrated in FIG. 27C, the second cutting line CT2 may not overlap the shape control block BLK in the third direction DR3, and when the second cutting line CT2 is shifted from one side surface BLK_S of the shape control block BLK to an opposite side in the second direction DR2 as illustrated in FIG. 27B, the second cutting line CT2 may not overlap the shape control block BLK in the third direction DR3.

The second cutting line CT2 and one side surface BLK_S of the shape control block BLK may form (or constitute) the residual trace RSD (refer to FIGS. 4 and 10) after a process of the method S1 for manufacturing the display device is completed. Since the residual trace RSD (refer to FIGS. 4 and 10) may overlap the shading portion BM (refer to FIGS. 4 and 10) as described above with reference to FIGS. 4 and 10, the second cutting line CT2 and one side surface BLK_S of the shape control block BLK may overlap the light-blocking portion BM (refer to FIGS. 4 and 10) in the third direction DR3 after the process of the method S1 for manufacturing the display device is completed regardless of a case where the second cutting line CT2 overlaps one side surface BLK_S of the shape control block BLK in the third direction DR3 and a case where the second cutting line CT2 does not overlap one side surface BLK_S of the shape control block BLK in the third direction DR3.

Next, as illustrated in FIGS. 22, 29, and 30, the display panel 100, the polarizing layer POL, and the base layer BSL may be bonded to each other (refer to the operation S300 of FIG. 19).

The polarizing layer POL may be disposed on the display panel 100, and the base layer BSL may be disposed on the polarizing layer POL.

A size or an area of the base layer BSL in a plan view may be greater than a size or an area of the display panel 100 in a plan view, and the size or the area of the display panel 100 in a plan view may be greater than a size or an area of the polarizing layer POL in a plan view.

As illustrated in FIG. 29, an opposite end of the base layer BSL in the second direction DR2 may protrude more than an opposite end of the display panel 100 in the second direction DR2, and an opposite end of the display panel 100 in the second direction DR2 may protrude more than an opposite end of the polarizing layer POL in the second direction DR2.

The first cutting line CT1 may be disposed on an opposite side in the second direction DR2 more than the second cutting line CT2. The first cutting line CT1 may not overlap the second cutting line CT2 in the third direction DR3, and may overlap the shape control block BLK in the third direction DR3.

Next, as illustrated in FIGS. 23, 31, and 32, the coating layer CTL may be formed on the base layer BSL (refer to the operation S400 of FIG. 19).

A coating device CD may discharge ink INK onto the base layer BSL. The ink INK may include a liquid polymer resin. The coating device CD may perform slit coating, jetting, or inkjet coating.

In some embodiments, when the coating device CD performs the slit coating, a scan direction of the coating device CD may be parallel to the second cutting line CT2. In addition, an extension direction of each of individual shots SHOT discharged by slits of the coating device CD may cross (e.g., be perpendicular) to the second cutting line CT2.

In an embodiment, the coating device CD may discharge shots SHOT extending in the second direction DR2 by the slits extending in the second direction DR2 or discharge ports disposed in parallel in the second direction DR2, for example. The coating device CD may apply the ink INK onto the base layer BSL by continuously discharging the shots SHOT while moving (scanning) in the first direction DR1.

In the method S1 for manufacturing the display device in the illustrated embodiment, the second cutting line CT2 is parallel to the scan direction of the coating device CD and crosses the extension direction of the shot SHOT of the coating device CD, and thus, deformation of and damage to the base layer BSL due to a pressure applied to the second cutting line CT2 may be minimized. In a case of the slit coating, a selected pressure may be applied to the slits or the discharge ports in order to discharge the ink INK, and such a pressure may also be applied to the second cutting line CT2 of the base layer BSL. In this case, when the second cutting line CT2 is parallel to the scan direction of the coating device CD and crosses the extension direction of the shot SHOT of the coating device CD, one point of the second cutting line CT2 and the shot SHOT cross each other only at one point, and thus, a pressure applied to each point of the second cutting line CT2 may be minimized. Accordingly, deformation of and damage to the base layer BSL may be minimized.

The second cutting line CT2 and the shot SHOT do not necessarily need to be perpendicular to each other, and a pressure applied to the second cutting line CT2 may be minimized just by making the second cutting line CT2 and the shot SHOT cross each other at one point.

Although not illustrated in FIGS. 23, 31, and 32, the ink INK may be cured by a separate curing device. In an embodiment, the ink INK may be cured through ultra-violet (“UV”) curing, heat curing, or natural curing. The ink INK may be cured to form the coating layer CTL, for example.

The coating layer CTL may have a greater thickness at an edge thereof than at a central portion thereof due to surface tension or the like. In an embodiment, the coating layer CTL may include a bump structure formed along the edge of the coating layer CTL. It has been illustrated in FIG. 31 that bumps BMP are disposed at opposite ends of the coating layer CTL in the second direction DR2, but the bumps BMP may also be disposed at opposite ends of the coating layer CTL in the first direction DR1, and accordingly, the bumps BMP may be formed at the entirety of the edge portion of the coating layer CTL, for example. The central portion of the coating layer CTL excluding the bumps BMP may be substantially flat. That is, the coating layer CTL may have a basin shape whose edge is raised and central portion is flat.

In some embodiments, the ink INK may be applied at a greater height than the shape control block BLK. In an embodiment, a height of the coating layer CTL (length of the coating layer CTL in the third direction DR3) after the ink INK is cured may be greater than a height of the shape control block BLK (length of the shape control block BLK in the third direction DR3), for example.

Next, as illustrated in FIGS. 24, 33, and 34, the third cutting line CT3 may be formed in the display panel 100, the polarizing layer POL, the base layer BSL, and the coating layer CTL (refer to the operation S500 of FIG. 19).

The third cutting line CT3 may be a hole continuously penetrating through the display panel 100, the polarizing layer POL, and the base layer BSL bonded to each other and the coating layer CTL. The third cutting line CT3 may be formed by the laser processing device LD. The laser processing device LD may form the third cutting line CT3 by irradiating the display panel 100, the polarizing layer POL, the base layer BSL, and the coating layer CTL with a laser beam LS.

Residual traces may be formed around the third cutting line CT3 by heat energy of the laser beam LS. In an embodiment, a first residual trace HAZ1 may be formed around the third cutting line CT3 in the base layer BSL, a second residual trace HAZ2 may be formed around the third cutting line CT3 in the coating layer CTL, a fourth residual trace HAZ3 may be formed around the third cutting line CT3 in the display panel 100, and a fifth residual trace HAZ4 may be formed around the third cutting line CT3 in the polarizing layer POL, for example.

The first residual trace HAZ1, the second residual trace HAZ2, the fourth residual trace HAZ3, and the fifth residual trace HAZ4 may surround the third cutting line CT3. In an embodiment, the first residual trace HAZ1, the second residual trace HAZ2, the fourth residual trace HAZ3, and the fifth residual trace HAZ4 may be HAZs formed by local heat of a laser beam, for example. The first residual trace HAZ1, the second residual trace HAZ2, the fourth residual trace HAZ3, and the fifth residual trace HAZ4 may be zones where properties of materials included in the base layer BSL, the coating layer CTL, the display panel 100, and the polarizing layer POL are changed due to a local relatively high temperature state caused by the irradiation of the laser beam LS, respectively.

Physical, chemical, structural, and optical characteristics of the first residual trace HAZ1 may be different from physical, chemical, structural, and optical characteristics of remaining (the other) portions of the base layer BSL excluding the first residual trace HAZ1. Physical, chemical, structural, and optical characteristics of the second residual trace HAZ2 may be different from physical, chemical, structural, and optical characteristics of remaining (the other) portions of the coating layer CTL excluding the second residual trace HAZ2. Physical, chemical, structural, and optical characteristics of the fourth residual trace HAZ3 may be different from physical, chemical, structural, and optical characteristics of remaining (the other) portions of the display panel 100 excluding the fourth residual trace HAZ3. Physical, chemical, structural, and optical characteristics of the fifth residual trace HAZ4 may be different from physical, chemical, structural, and optical characteristics of remaining (the other) portions of the polarizing layer POL excluding the fifth residual trace HAZ4.

When the materials included in the display panel 100, the polarizing layer POL, the base layer BSL, and the coating layer CTL are different from each other, physical, chemical, structural, and optical characteristics of the first residual trace HAZ1, the second residual trace HAZ2, the fourth residual trace HAZ3, and the fifth residual trace HAZ4 may be different from each other.

The third cutting line CT3 may correspond to a shape of the display panel 100. In an embodiment, when the display panel 100 has a quadrangular shape, e.g., rectangular shape in a plan view, the third cutting line CT3 may also have a quadrangular shape, e.g., rectangular shape in a plan view, for example.

Sides respectively next (adjacent) to the first side surface SS1, the third side surface SS3, and the fourth side surface SS4 among sides of the third cutting line CT3 may be disposed inside the display panel 100 and the polarizing layer POL in a plan view. That is, the sides respectively next (adjacent) to the first side surface SS1, the third side surface SS3, and the fourth side surface SS4 among the sides of the third cutting line CT3 may be surrounded by neighboring (adjacent) sides of the display panel 100 and the polarizing layer POL in a plan view.

A side next (adjacent) to the second side surface SS2 among the sides of the third cutting line CT3 may be disposed outside the display panel 100 and the polarizing layer POL in a plan view. The side next (adjacent) to the second side surface SS2 among the sides of the third cutting line CT3 may be disposed on an opposite side in the second direction DR2 more than the first cutting line CT1 and the second cutting line CT2 and be more next (adjacent) to the second side surface SS2 than the first cutting line CT1 and the second cutting line CT2 are.

Accordingly, sides extending in the second direction DR2 among the sides of the third cutting line CT3 may cross the first cutting line CT1 and the second cutting line CT2.

With the method S1 for manufacturing the display device in the illustrated embodiment, a process of leaving only a flat portion of the coating layer CTL by removing the bumps BMP of the coating layer CTL may be performed simultaneously with a process of cutting an outer shape of the display panel 100 and the polarizing layer POL. Accordingly, a process time and cost may be reduced.

The third cutting line CT3 may cut the display panel 100, the polarizing layer POL, the base layer BSL, and the coating layer CTL at once, whereas the first cutting line CT1 and the second cutting line CT2 may cut the display panel 100 and the base layer BSL, respectively. Since the display pad portion DP (refer to FIG. 3) is disposed in the sub-area SBA of the display panel 100, there is a risk of damage to the display pad portion DP (refer to FIG. 3) when the display panel 100, the polarizing layer POL, the base layer BSL, and the coating layer CTL are cut at once through the third cutting line CT3.

Therefore, in the method S1 for manufacturing the display device in the illustrated embodiment, by forming the first cutting line CT1 and the second cutting line CT2 in advance as pre-cut lines separately from the third cutting line CT3, it is possible to prevent the damage to the display pad portion DP (refer to FIG. 3). In addition, by making each of the first cutting line CT1 and the second cutting line CT2 cross the third cutting line CT3, a perimeter (e.g., four sides) may be completely cut.

Since the display panel 100, the polarizing layer POL, the base layer BSL, and the coating layer CTL are cut at once through the third cutting line CT3, respective side surfaces of the display panel 100, the polarizing layer POL, the base layer BSL, and the coating layer CTL on the first side surface SS1, the third side surface SS3, and the fourth side surface SS4 may be disposed in parallel with each other in a straight line.

Next, as illustrated in FIGS. 25, 35, and 36, the dummy areas DUM of the display panel 100, the polarizing layer POL, the base layer BSL, and the coating layer CTL may be split and removed along the first to third cutting lines CT1, CT2, and CT3 (refer to the operation S600 of FIG. 19).

A perimeter of the display panel 100 may be completely cut by the first cutting line CT1 and the third cutting line CT3, such that the dummy area DUM may be separated. In an embodiment, sides corresponding to the first side surface SS1, the third side surface SS3, and the fourth side surface SS4 among sides of the display panel 100 may be cut along the third cutting line CT3, and a side corresponding to the second side surface SS2 among the sides of the display panel 100 may be cut along the first cutting line CT1, for example.

A perimeter of the polarizing layer POL may be completely cut along the third cutting line CT3, such that the dummy area DUM may be separated. In an embodiment, sides corresponding to the first side surface SS1, the third side surface SS3, and the fourth side surface SS4 among sides of the polarizing layer POL may be cut along the third cutting line CT3, for example. A side corresponding to the second side surface SS2 among the sides of the polarizing layer POL is disposed on one side in the second direction DR2 more than the first cutting line CT1 and the second cutting line CT2, and may thus be maintained as an original side without being cut.

A perimeter of the base layer BSL may be completely cut by the second cutting line CT2 and the third cutting line CT3, such that the dummy area DUM may be separated. In an embodiment, sides corresponding to the first side surface SS1, the third side surface SS3, and the fourth side surface SS4 among sides of the base layer BSL may be cut along the third cutting line CT3, and a side corresponding to the second side surface SS2 among the sides of the base layer BSL may be cut along the second cutting line CT2, for example.

The coating layer CTL may be split along one side surface BLK_S of the shape control block BLK, as illustrated in FIGS. 35 and 36. However, since the height of the coating layer CTL (length of the coating layer CTL in the third direction DR3) is greater than the height of the shape control block BLK (length of the shape control block BLK in the third direction DR3) as described above, the coating layer CTL may be split by physical pressing force at a portion that is not in contact with the one side surface BLK_S of the shape control block BLK.

In this process, the third residual trace BLR may be formed on a side surface of the coating layer CTL at the portion that is not in contact with one side surface BLK_S of the shape control block BLK. The third residual trace BLR may be the fine projection such as the burr as described above. The third residual trace BLR may not be viewed by the light-blocking portion BM of the upper protection layer PL or the upper protection member PLM, as described above.

In some embodiments, when the shape control block BLK includes a protrusion portion BLK_P as illustrated in FIG. 36, the coating layer CTL may be easily split even with smaller pressing force.

Hereinafter, another embodiment of the method for manufacturing a display device in an embodiment will be described. In the following embodiments, the same components as those of the above-described embodiment will be denoted by the same reference numerals, and an overlapping description thereof will be omitted or simplified and contents different from those described above will be mainly described.

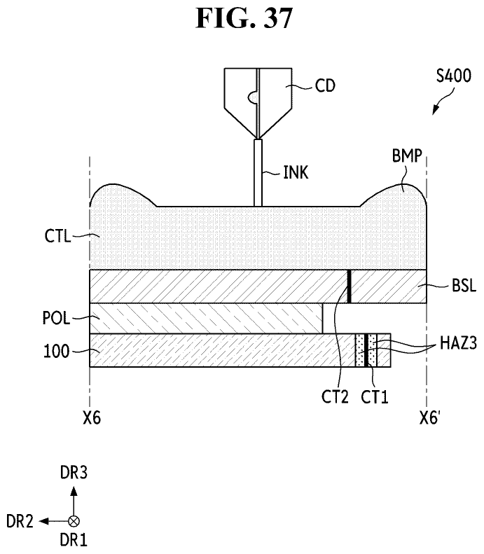

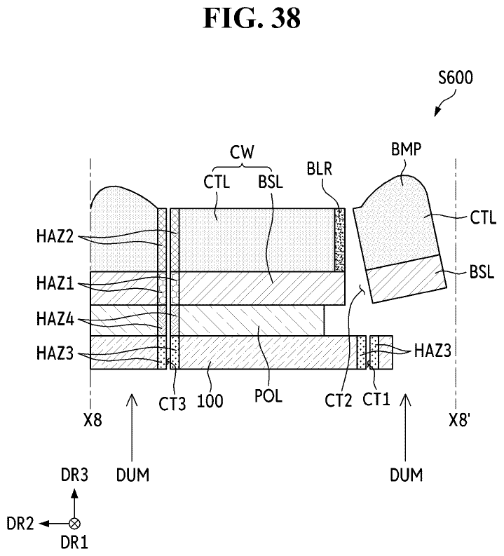

FIG. 37 is a cross-sectional view illustrating another embodiment of the operation S400 of a method for manufacturing a display device. FIG. 38 is a cross-sectional view illustrating another embodiment of the operation S600 of the method for manufacturing a display device of FIG. 36.

Referring to FIGS. 37 and 38, with a method S1 for manufacturing a display device in another embodiment, a dummy area may be split from the coating layer CTL without the shape control block BLK.

In an embodiment, as illustrated in FIG. 37, when the coating device CD discharges ink INK onto the base layer BSL, there may be no shape control block BLK on the base layer BSL, for example. Accordingly, the ink INK may be applied onto the entirety of the upper surface of the base layer BSL (S400 of FIG. 37).

Then, as illustrated in FIG. 38, the dummy areas DUM of the base layer BSL and the coating layer CTL may be removed along the second cutting line CT2 (refer to the operation S600 of FIG. 38).

When the base layer BSL is separated by the second cutting line CT2, the coating layer CTL may be split together by physical pressing force. In this process, the third residual trace BLR may be formed on a side surface of the coating layer CTL. The third residual trace BLR may be formed on the entirety of a side surface of the coating layer CTL in a thickness direction of the coating layer CTL.

That is, in the method S1 for manufacturing the display device in an embodiment described above with reference to FIGS. 19 to 36, the third residual trace BLR may be formed on the side surface of the coating layer CTL only at the portion that is not in contact with one side surface BLK_S of the shape control block BLK, whereas in the method S1 for manufacturing the display device in the illustrated embodiment, the third residual trace BLR may be formed on the entirety of side surface of the coating layer CTL in the thickness direction of the coating layer CTL.

When a thickness of the coating layer CTL (length of the coating layer CTL in the third direction DR3) is smaller than a selected level, the coating layer CTL may be slit by the physical pressing force along the second cutting line CT2 without the shape control block BLK, as in the illustrated embodiment. When the thickness of the coating layer CTL (length of the coating layer CTL in the third direction DR3) is greater than the selected level, the coating layer CTL may be slit using the shape control block BLK, as in an embodiment described above with reference to FIGS. 19 to 36.

The display device 10 according to the above-described embodiment may be applied to various electronic devices 1. The electronic device 1 in an embodiment may include the display device 10 described above, and may further include a module or a device having an additional function in addition to the display device 10.

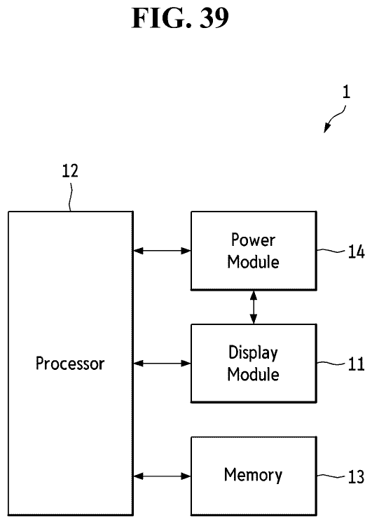

FIG. 39 is a block diagram of an embodiment of an electronic device.

Referring to FIG. 39, an electronic device 1 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for an operation of the processor 12 or the display module 11. When the processor 12 executes an application stored in the memory 13, an image data signal (or image driving signal) and/or an input control signal may be transmitted to the display module 11, and the display module 11 may process the received signal and output image information through a display screen.

The power module 14 may include a power supply module such as a power adapter or a battery device and a power conversion module converting power supplied by the power supply module to generate power desired for an operation of the electronic device 1.

At least one of the respective components of the above-described electronic device 1 may be included in the display device 10 according to the above-described embodiments. In addition, some of individual modules functionally included in one module may be included in the display device 10, and remaining (the other) individual modules of the individual modules may be provided separately from the display device 10. In an embodiment, the display device 10 may include the display module 11, and the processor 12, the memory 13, and the power module 14 may be provided in the form of other devices within the electronic device 1 rather than the display device 10, for example.

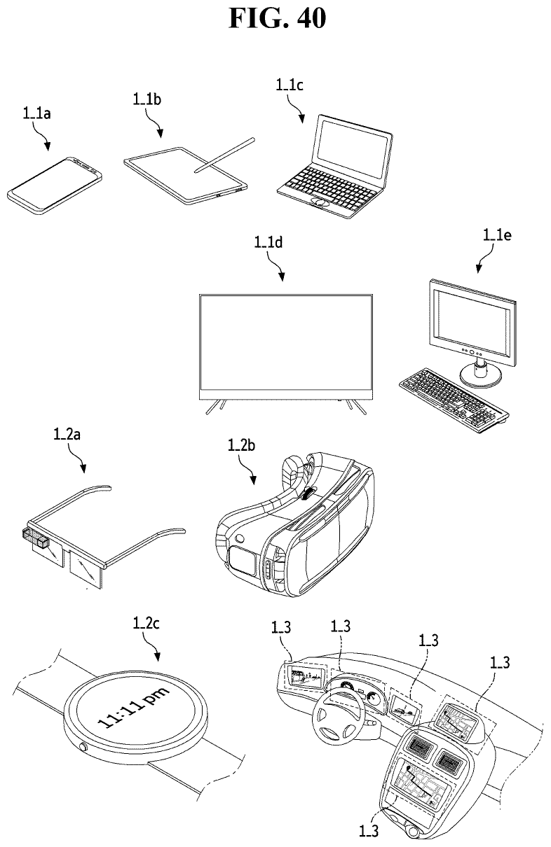

FIG. 40 is schematic views of embodiments of electronic devices.

Referring to FIG. 40, various electronic devices 1 to which the display device 10 in embodiments is applied may include not only image display electronic devices 1 such as a smartphone 1_1a, a tablet PC 1_1b, a laptop computer 1_1c, a television (“TV”) 1_1d, and a monitor 1_1e for a desktop computer, but also wearable electronic devices 1 including display modules, such as a smart glasses 1_2a, a head mounted display 1_2b, and a smart watch 1_2c, and vehicle electronic devices 1_3 including display modules, such as a center information display (“CID”) disposed on an instrument board, a center fascia, or a dashboard of a vehicle and a room mirror display.

In concluding the detailed description, those skilled in the art will appreciate that many variations and modifications may be made to the preferred embodiments without substantially departing from the principles of the disclosure. Therefore, the disclosed preferred embodiments of the disclosure are used in a generic and descriptive sense only and not for purposes of limitation.

What is claimed is:

1. A display device comprising:
a display panel including:
a main area; and
a sub-area disposed on one side of the main area and configured to be bendable; and
a cover window including:
a base layer disposed on the display panel; and
a coating layer disposed on the base layer,
a first residual trace disposed on a first side next to the sub-area; and
a second residual trace disposed on at least one of remaining sides of the cover window excluding the first side.

2. The display device of claim 1, wherein the first residual trace is disposed on a side surface of the coating layer on the first side, and
the second residual traces are disposed on the base layer and the coating layer, respectively, on the at least one side.

3. The display device of claim 2, wherein the first residual trace is disposed only on a portion of the side surface of the coating layer, and is next to an upper surface of the coating layer.

4. The display device of claim 2, wherein the first residual trace is a burr and the second residual trace is a heat-affected zone.

5. The display device of claim 2, wherein the second residual trace disposed on the base layer and the second residual trace disposed on the coating layer have different properties.

6. The display device of claim 1, wherein the coating layer includes a chamfered surface disposed between a side surface and an upper surface, and
the first residual trace is disposed on the chamfered surface of the coating layer on the first side.

7. The display device of claim 1, wherein on a side corresponding to the at least one side of the cover window, a side surface of the display panel is disposed in a straight line with a side surface of the cover window.

8. The display device of claim 7, wherein the display panel includes a third residual trace on the side corresponding to the at least one side of the cover window.

9. The display device of claim 8, wherein the third residual trace is a heat-affected zone.

10. The display device of claim 1, further comprising an upper protection layer disposed on the cover window,
wherein the upper protection layer includes a light-blocking portion overlapping the first residual trace and the second residual trace.

11. The display device of claim 1, further comprising a polarizing layer disposed between the display panel and the cover window.

12. A method for manufacturing a display device, the method comprising:
forming a first cutting line in a display panel;
forming a second cutting line in a base layer;
bonding the display panel and the base layer to each other;
forming a coating layer on the base layer;
forming a third cutting line in the display panel, the base layer, and the coating layer; and
splitting and removing dummy areas of the display panel, the base layer, and the coating layer along the first cutting line, the second cutting line, and the third cutting line,
wherein the third cutting line crosses each of the first cutting line and the second cutting line.

13. The method for manufacturing the display device of claim 12, wherein the first cutting line is next to one side of the display panel, and
the second cutting line is next to the one side of the display panel.

14. The method for manufacturing the display device of claim 12, wherein the first cutting line and the third cutting line are formed using a laser beam.

15. The method for manufacturing the display device of claim 12, wherein the third cutting line continuously penetrates through the display panel, the base layer, and the coating layer.

16. The method for manufacturing the display device of claim 12, wherein the coating layer is formed by applying ink by a coating device, and
a scan direction of the coating device is parallel to an extension direction of the second cutting line.

17. The method for manufacturing the display device of claim 12, wherein a shape control block is disposed on the base layer, and
a height of the coating layer is greater than a height of the shape control block.

18. The method for manufacturing the display device of claim 17, wherein a burr is formed by removing a portion of the coating layer disposed at a higher level than the shape control block.

19. The method for manufacturing the display device of claim 17, wherein the shape control block includes a protrusion portion.

20. An electronic device comprising:
a display device configure to display an image, the display device including:
a display panel including a main area and a sub-area disposed on one side of the main area and configured to be bendable; and
a cover window including:
a base layer disposed on the display panel;
a coating layer disposed on the base layer;
a first residual trace disposed on a first side next to the sub-area; and
a second residual trace disposed on at least one of remaining sides of the cover window excluding the first side,
a processor configure to provide an image driving signal to the display device; and
a power module configure to supply power to the display device and the processor.
